(19) United States
(12) Patent Application Publication
(10) Pub. No.: US 2018/0248572 A1
(43) Pub. Date: Aug. 30, 2018

(54) COMMUNICATION DEVICE, COMMUNICATION METHOD, AND CANCELLATION DEVICE

(71) Applicant: FUJITSU LIMITED, Kawasaki-shi (JP)

(72) Inventors: HIROYOSHI ISHIKAWA, Kawasaki (JP); YUSUKE OKI, Kawasaki (JP)

(73) Assignee: FUJITSU LIMITED, Kawasaki-shi (JP)

(21) Appl. No.: 15/904,501

(22) Filed: Feb. 26, 2018

(30) Foreign Application Priority Data
Feb. 27, 2017 (JP) 2017-035288

(51) Int. Cl. H04B 1/04; H03D 7/16; H04B 1/00; H04L 25/02

(52) U.S. Cl. CPC H04B 1/0475; H03D 7/161; H04B 2001/485; H04L 25/022; H04B 1/0096

(57) ABSTRACT

There is provided a communication device including a first transmitter configured to up-convert a frequency of a first transmission signal to a first frequency so as to be wirelessly transmitted, a second transmitter configured to up-convert a frequency of a second transmission signal to a second frequency different from the first frequency so as to be wirelessly transmitted, a receiver configured to receive a reception signal including a passive intermodulation signal generated due to the first and second transmission signals wirelessly transmitted, a memory, and a processor coupled to the memory and configured to estimate frequency errors of the up-converted first and second transmission signals, generate a cancellation signal into which any frequency of the first and second transmission signals has been corrected, based on the estimated frequency errors, and combine the cancellation signal with a down-converted reception signal.

### CROSS-REFERENCE TO RELATED APPLICATION

This application is based upon and claims the benefit of priority of the prior Japanese Patent Application No. 2017-035288, filed on Feb. 27, 2017, the entire contents of which are incorporated herein by reference.

### FIELD

The embodiments discussed herein are related to a communication device, a communication method, and a cancellation device.

### BACKGROUND

In the related art, a duplexer may be provided in each of radio communication devices sharing an antenna for transmission and reception. That is, when the frequencies of a transmission signal and a reception signal are different from each other, the duplexer is connected to the antenna, and a transmission path and a reception path in the radio communication device are electrically separated from each other. Thus, the transmission signal does not interfere with the reception signal, and a deterioration of a reception quality may be suppressed.

In recent years, a multicarrier transmission has been practically performed transmitting signals with a plurality of carriers having different frequencies. In the multicarrier transmission, transmission signals include signals having a plurality of different frequencies, and thus, an intermodulation (passive intermodulation) signal (also referred to as a “PIM signal”) may be generated by the intermodulation of the signals having the different frequencies. The intermodulation signal generated from the transmission signals leaks into the reception path and deteriorates the reception quality. Especially, when the frequency of the intermodulation signal generated from the transmission signals is included in a frequency band of a reception signal, it becomes difficult to accurately demodulate and decode the reception signal.

In addition, for example, the duplexer, the antenna, and a cable that connects the duplexer and the antenna to each other, are passive elements, and the extent of contribution of these passive elements to an occurrence of a nonlinear distortion is relatively small, as compared with the active elements such as an amplifier. However, the intermodulation signal generated from the transmission signals may leak into the reception path and deteriorate the reception quality, due to a minute impedance change or a nonlinear characteristic in the passive elements. Further, the intermodulation signal generated from the transmission signals may be reflected into the reception path and deteriorate the reception quality, due to, for example, a metal existing outside the radio communication device. Accordingly, for example, it has been considered to approximately reproduce the intermodulation signal from the transmission signals and an interference signal, and cancel the intermodulation signal by the reproduced signal. The intermodulation signal reproduced from the transmission signals and the interference signal is adaptively controlled by, for example, an adaptive filter to reduce an error with respect to the intermodulation signal included in the reception signal.

Related technologies are disclosed in, for example, Japanese National Publication of International Patent Application No. 2009-526442.

Related technologies are disclosed in, for example, “Passive Intermodulation (PIM) Handling for Base Stations (BS) (Release12),” 3 GPPTR37.808 v 12.0.0.

### SUMMARY

According to an aspect of the invention, a communication device includes a first transmitter configured to up-convert a frequency of a first transmission signal to a first frequency so as to be wirelessly transmitted, a second transmitter configured to up-convert a frequency of a second transmission signal to a second frequency different from the first frequency so as to be wirelessly transmitted, a receiver configured to receive a reception signal including a passive intermodulation signal generated due to the first transmission signal wirelessly transmitted and the second transmission signal wirelessly transmitted, and down-convert the reception signal to a baseband signal, a memory, and a processor coupled to the memory and the processor configured to, estimate frequency errors of the up-converted first transmission signal and the up-converted second transmission signal, generate a cancellation signal into which any frequency of the first transmission signal and the second transmission signal has been corrected, based on the estimated frequency errors, wherein the cancellation signal is a replica signal for the passive intermodulation signal, and combine the cancellation signal with the down-converted reception signal.

The object and advantages of the disclosure will be realized and attained by means of the elements and combinations particularly pointed out in the claims.

It is to be understood that both the foregoing general description and the following detailed description are exemplary and explanatory and are not restrictive of the disclosure, as claimed.

### BRIEF DESCRIPTION OF DRAWINGS

FIG. 1 is a block diagram illustrating an example of a communication device according to Embodiment 1;

FIG. 2 is a view illustrating an example of a PIM signal included in a reception signal;

FIG. 3 is a block diagram illustrating an example of a cancellation device according to Embodiment 1;

FIG. 4 is a view for explaining an example of a frequency error estimating method according to Embodiment 1;

FIG. 5 is a view illustrating an example of a change of a residual PIM;

FIG. 6 is a flowchart illustrating an example of processes performed by the communication device according to Embodiment 1;

FIG. 7 is a block diagram illustrating another example of the cancellation device according to Embodiment 1;

FIG. 8 is a block diagram illustrating yet another example of the cancellation device according to Embodiment 1;

FIG. 9 is a block diagram illustrating yet another example of the terminal device according to Embodiment 1;

FIG. 10 is a block diagram illustrating yet another example of the cancellation device according to Embodiment 1;

FIG. 11 is a block diagram illustrating yet another example of the cancellation device according to Embodiment 1;

FIG. 12 is a block diagram illustrating an example of a cancellation device according to Embodiment 2;

FIG. 13 is a view for explaining an example of a frequency error estimating method according to Embodiment 2;

FIG. 14 is a block diagram illustrating an example of a communication device according to Embodiment 3;

FIG. 15 is a block diagram illustrating an example of a cancellation device according to Embodiment 4;

FIG. 16 is a view illustrating an example of an instantaneous value table;

FIG. 17 is a view for explaining an example of an interpolating method; and

FIG. 18 is a block diagram illustrating an example of hardware of a cancellation device.

### DESCRIPTION OF EMBODIMENTS

In a case where transmission signals having different frequencies are transmitted from different radio base stations and when a nonlinear distortion occurrence source such as a metal exists on a transmission path of the transmission signals, an intermodulation signal is generated by intermodulation of the transmission signals having different frequencies. Further, in addition to an uplink signal transmitted from a radio terminal, the intermodulation signal is superimposed on a signal received in an antenna of each radio base station. In each radio base station, a cancellation signal for canceling the corresponding intermodulation signal is generated based on the intermodulation signal included in the reception signal, and the generated cancellation signal is combined with the reception signal. As a result, the intermodulation signal is canceled from the reception signal.

In each radio base station, a transmission signal of a baseband is up-converted to a desired frequency by using a local oscillation signal generated by an oscillator provided in the radio base station. However, the local oscillation signal in each radio base station has a slight error with respect to the desired frequency, and the errors of the respective radio base stations are generally different from each other in the radio base stations. Further, since the oscillators in the respective radio base stations operate independently, the fluctuations of the frequencies of the local oscillation signals generated by the oscillators also occur independently. Accordingly, the frequency errors of the transmission signals transmitted from the respective radio base stations are different from each other in the radio base stations. Further, in a case where one radio base station has a plurality of transmitters, when the oscillators in the respective transmitters operate independently, the frequency errors of the transmission signals of the respective transmitters are different from each other.

Thus, the intermodulation signal included in the reception signal is generated by the plurality of transmission signals having different frequency errors. Accordingly, even though the cancellation signal generated by presupposing that the cancellation signal is to be transmitted at a desired frequency is combined with the reception signal, it may be difficult to sufficiently reduce the intermodulation signal included in the reception signal, and it may become difficult to improve the reception quality.

Hereinafter, embodiments of a technology for improving the reception quality will be described in detail with reference to the accompanying drawings. However, it is noted that the present disclosure is not limited by the embodiments. Further, the embodiments may be appropriately combined with each other within a scope that does not cause any inconsistency in process contents.

### First Embodiment

<Communication Device 10>

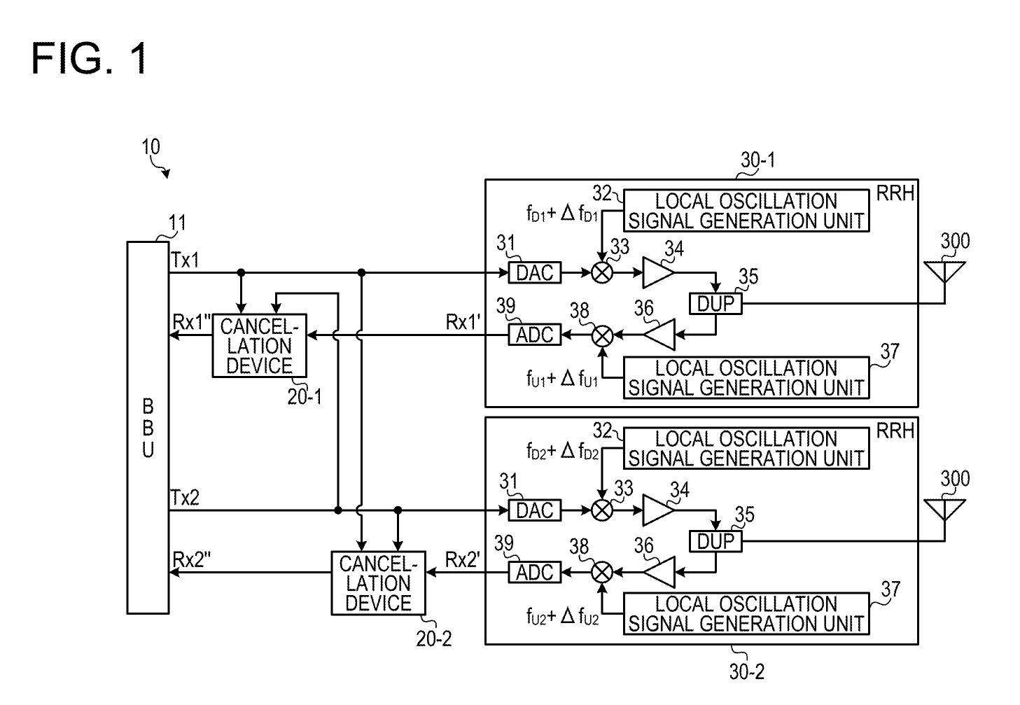

FIG. 1 is a block diagram illustrating an example of a communication device 10 according to Embodiment 1. The communication device 10 includes a base band unit (BBU) 11, cancellation devices 20-1 and 20-2, and remote radio heads 30-1 and 30-2. In this embodiment, for example, the communication device 10 is a radio base station used for a radio communication system. The RRHs 30-1 and 30-2 transmit transmission signals of different frequencies, respectively, and receive reception signals of different frequencies, respectively. In this embodiment, the RRH 30-1 transmits a transmission signal Tx1 at a frequency f_{D1} and receives a reception signal at a frequency f_{U1}. Further, in this embodiment, the RRH 30-2 transmits a transmission signal Tx2 at a frequency f_{D2} and receives a reception signal at a frequency f_{U2}.

In the descriptions hereinbelow, it is assumed that f_{D1}<f_{D2}. Further, in the descriptions hereinbelow, the cancellation devices 20-1 and 20-2 will be simply referred to as the “cancellation devices 20” when they are collectively referred to without being discriminated, and the RRHs 30-1 and 30-2 will be simply referred to as the “RRHs 30” when they are collectively referred to without being discriminated. The transmission signal Tx1 is an example of a first transmission signal, and the transmission signal Tx2 is an example of a second transmission signal. Further, the frequency f_{D1} is an example of a first frequency, and the frequency f_{D2} is an example of a second frequency. The RRH 30-1 is an example of a first transmitter, and the RRH 30-2 is an example of a second transmitter.

Each RRH 30 includes a digital-to-analog converter (DAC) 31, a local oscillation signal generation unit 32, an up-converter 33, a power amplifier (PA) 34, a Duplexer (DUP) 35, and an antenna 300. Further, each RRH 30 includes a low noise amplifier (LNA) 36, a local oscillation signal generation unit 37, a down-converter 38, and an analog-to-digital converter (ADC) 39.

The local oscillation signal generation unit 32 generates a local oscillation signal for up-converting a transmission signal from a baseband to an RF band. The local oscillation signal generation unit 32 is, for example, a local oscillator (LO). In this embodiment, the local oscillation signal generation unit 32 of the RRH 30-1 generates a local oscillation signal of a frequency f_{D1}+Δf_{D1}, and the local oscillation signal generation unit 32 of the RRH 30-2 generates a local oscillation signal having the frequency of f_{D2}+Δf_{D2}. In this embodiment, the local oscillation signal generated by the local oscillation signal generation unit 32 of the RRH 30-1 includes the error of Δf_{D1}, and the local oscillation signal generated by the local oscillation signal generation unit 32 of the RRH 30-2 includes the error of Δf_{D2}. In this embodiment, the local oscillation signal generation unit 32 of the RRH 30-1 and the local oscillation signal generation unit 32 of the RRH 30-2 generate the local oscillation signals, respectively, by using signals output from different reference oscillators as references. Thus, Δf_{D1} and Δf_{D2} have different values from each other.

The local oscillation signal generation unit 37 generates a local oscillation signal for down-converting a reception signal from the RF band to the baseband. The local oscillation signal generation unit 37 is, for example, an LO. In this embodiment, the local oscillation signal generation unit 37 of the RRH 30-1 generates a local oscillation signal having the frequency of f_{U1}+Δf_{U1}, and the local oscillation signal generation unit 37 of the RRH 30-2 generates a local oscillation signal having the frequency of f_{U2}+Δf_{U2}. In this embodiment, the local oscillation signal generated by the local oscillation signal generation unit 37 of the RRH 30-1 includes the error of Δf_{U1}, and the local oscillation signal generated by the local oscillation signal generation unit 37 of the RRH 30-2 includes the error of Δf_{U2}. Further, in this embodiment, the local oscillation signal generation unit 37 of the RRH 30-1 and the local oscillation signal generation unit 37 of the RRH 30-2 generate the local oscillation signals, respectively, by using signals output from different reference oscillators as references.

The DAC 31 converts a transmission signal output from the BBU 11, from a digital signal into an analog signal, and outputs the converted transmission signal to the up-converter 33. The up-converter 33 up-converts the transmission signal of the baseband that has been converted into the analog signal by the DAC 31, to the frequency of the RF band by the local oscillation signal output from the local oscillation signal generation unit 32. In this embodiment, the up-converter 33 of the RRH 30-1 up-converts the transmission signal Tx1 of the baseband that has been converted into the analog signal by the DAC 31, to the frequency of f_{D1}+Δf_{D1} by the local oscillation signal output from the local oscillation signal generation unit 32. Similarly, the up-converter 33 of the RRH 30-2 up-converts the transmission signal Tx2 of the baseband that has been converted into the analog signal by the DAC 31, to the frequency of f_{D2}+Δf_{D2} by the local oscillation signal output from the local oscillation signal generation unit 32.

The PA 34 amplifies the transmission signal up-converted by the up-converter 33. The DUP 35 causes a frequency component of a transmission band in the transmission signal amplified by the PA 34, to pass through the antenna 300. Accordingly, the transmission signal up-converted to the RF band is radiated into a space from the antenna 300. Specifically, the transmission signal Tx1 up-converted to the frequency of f_{D1}+Δf_{D1} is radiated into a space from the antenna 300 of the RRH 30-1, and the transmission signal Tx2 up-converted to the frequency of f_{D2}+Δf_{D2} is radiated into a space from the antenna 300 of the RRH 30-2.

Further, the DUP 35 causes a frequency component of a reception band in a reception signal received via the antenna 300, to pass through the LNA 36. The LNA 36 amplifies the reception signal output from the DUP 35. The down-converter 38 down-converts the reception signal amplified by the LNA 36 from the frequency of the RF band to the frequency of the baseband by the local oscillation signal output from the local oscillation signal generation unit 37. The ADC 39 converts the reception signal down-converted by the down-converter 38 from an analog signal into a digital signal, and outputs the reception signal converted into the digital signal to the cancellation device 20. Specifically, the ADC 39 of the RRH 30-1 outputs the reception signal Rx1′ converted into the digital signal to the cancellation device 20-1, and the ADC 39 of the RRH 30-2 outputs the reception signal Rx2′ converted into the digital signal to the cancellation device 20-2.

In this embodiment, since the frequency of the local oscillation signal generated by the local oscillation signal generation unit 37 of the RRH 30-1 includes the error of Δf_{U1}, the down-converted reception signal includes the frequency error of Δf_{U1}. Similarly, since the frequency of the local oscillation signal generated by the local oscillation signal generation unit 37 of the RRH 30-2 includes the error of Δf_{U2}, the down-converted reception signal includes the frequency error of Δf_{U2}.

The cancellation device 20-1 acquires the transmission signal Tx1 transmitted by the RRH 30-1 and the transmission signal Tx2 transmitted by the RRH 30-2, from the BBU 11. Then, based on the transmission signals Tx1 and Tx2, the cancellation device 20-1 generates a cancellation signal which is a replica of the PIM signal generated due to the transmission signals Tx1 and Tx2. Then, the cancellation device 20-1 combines the generated cancellation signal with the reception signal Rx1′ output from the RRH 30-1, so as to reduce the PIM signal included in the reception signal Rx1′. Then, the cancellation device 20-1 outputs a reception signal Rx1″ in which the PIM signal is reduced, to the BBU 11.

Similarly, the cancellation device 20-2 also acquires the transmission signal Tx1 transmitted by the RRH 30-1 and the transmission signal Tx2 transmitted by the RRH 30-2, from the BBU 11, and generates a PIM signal based on the transmission signals Tx1 and Tx2. Then, the cancellation device 20-2 combines the generated cancellation signal with the reception signal Rx2′ output from the RRH 30-2, so as to reduce the PIM signal included in the reception signal Rx2′. Then, the cancellation device 20-2 outputs a reception signal Rx2″ in which the PIM signal is reduced, to the BBU 11.

In the descriptions hereinbelow, the reception signal Rx1′ output from the RRH 30-1 and the reception signal Rx2′ output from the RRH 30-2 will be simply referred to as the “reception signals Rx″” when the reception signal Rx1′ and the reception signal Rx2′ are collectively referred to without being discriminated. Further, the reception signal Rx1″ output from the cancellation device 20-1 and the reception signal Rx2″ output from the cancellation device 20-2 will be simply referred to as the “reception signals Rx″” when the reception signal Rx1″ and the reception signal Rx2″ are collectively referred to without being discriminated.

Here, the transmission signal Tx1 transmitted from the RRH 30-1 and the transmission signal Tx2 transmitted from the RRH 30-2 may be reflected on an external PIM source, and a PIM signal is generated. When the frequency of the transmission signal Tx1 is f_{D1} and the frequency of the transmission signal Tx2 is f_{D2}, a PIM signal of a frequency of, for example, 2f_{D1}−f_{D2} or 2f_{D2}−f_{D1} is generated by the transmission signals Tx1 and Tx2.

Thus, for example, when the frequency of 2f_{D1}−f_{D2} is included in the reception band of the communication device 10, a replica of the PIM signal corresponding to the frequency of 2f_{D1}−f_{D2} is generated from the transmission signals Tx1 and Tx2. Then, the generated replica of the PIM signal is combined with the reception signal Rx′ which has been down-converted to the baseband, so that the PIM signal corresponding to the frequency of 2f_{D1}−f_{D2} is canceled from the reception signal Rx′.

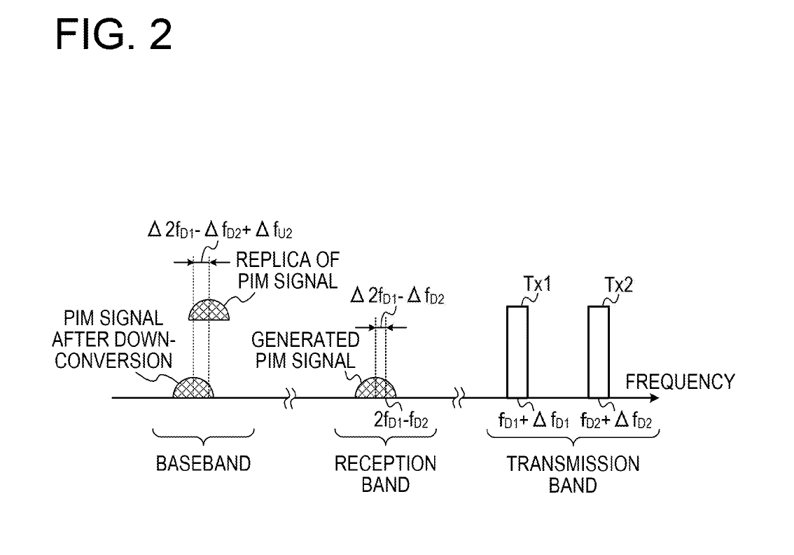

However, in this embodiment, for example, as illustrated in FIG. 2, the transmission signal Tx1 includes the frequency error of Δf_{D}1, and the transmission signal Tx2 includes the frequency error of Δf_{D2}. Thus, the frequency of the PIM signal generated by the transmission signals Tx1 and Tx2 is a frequency shifted by 2Δf_{D1}−Δf_{D2}from 2f_{D1}−f_{D2}. FIG. 2 is a view illustrating an example of the PIM signal included in the reception signal.

In addition, when the reception signal is down-converted from the RF band to the baseband, the influence of the frequency error of the local oscillation signal used for the down-conversion remains on the down-converted reception signal Rx′. For example, the reception signal Rx2′ down-converted by the RRH 30-2 includes the frequency error Δf_{U2} of the local oscillation signal generation unit 37 of the RRH 30-2. Accordingly, the reception signal Rx2′ down-converted to the baseband by the RRH 30-2 includes a PIM signal of a frequency shifted by 2Δf_{D1}−Δf_{D2}+Δf_{U2} from a desired frequency.

Here, it is assumed that a replica of the PIM signal corresponding to the frequency of 2f_{D1}−f_{D2} is generated, and the generated replica of the PIM signal is combined with the reception signal, without considering the frequency error of the local oscillation signal of each RRH 30. In this case, for example, as illustrated in FIG. 2, the frequency error of 2Δf_{D1}−Δf_{D2}+Δf_{U2} exists between the PIM signal included in the reception signal which has been down-converted to the baseband and the replica of the PIM signal. Thus, even though the replica of the PIM signal is combined with the reception signal, it is difficult to eliminate the PIM signal included in the reception signal. Therefore, it is difficult to improve the quality of the reception signal.

Thus, in this embodiment, the cancellation device 20 estimates the frequency errors of the respective transmission signals Tx1 and Tx2, and corrects the frequency of the replica of the PIM signal based on the estimated frequency errors, in the process of generating the replica of the PIM signal. As a result, it is possible to make the frequency of the replica of the PIM signal close to the frequency of the PIM signal included in the reception signal down-converted to the baseband. Thus, when the replica of the PIM signal is combined with the reception signal, the PIM signal included in the reception signal may be effectively suppressed, and the quality of the reception signal may be improved.

<Cancellation Device 20>

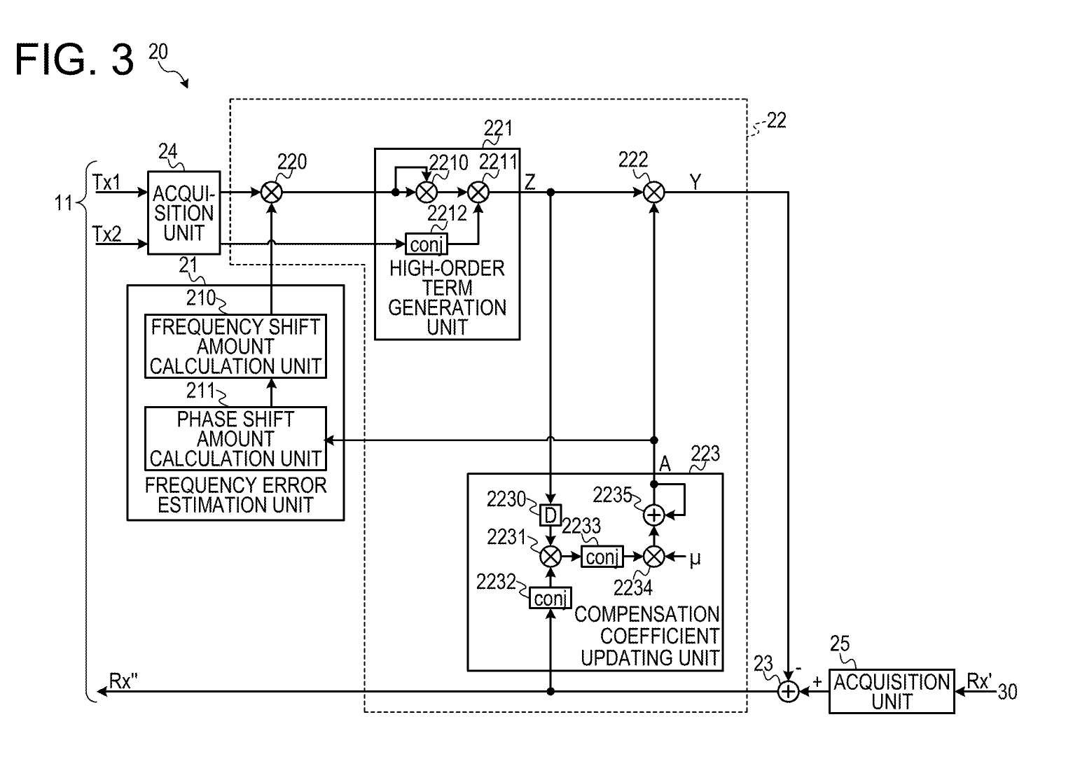

FIG. 3 is a block diagram illustrating an example of the cancellation device 10 according to First Embodiment. In this embodiment, for example, as illustrated in FIG. 3, each cancellation device 20 includes a frequency error estimation unit 21, a generation unit 22, a combination unit 23, and acquisition units 24 and 25. In the descriptions hereinbelow, the reduction of the PIM signal corresponding to the frequency of 2f_{D1}−f_{D2} will be described. However, the reduction of the PIM signal corresponding to the frequency of 2f_{D2}−f_{D1} may also be similarly implemented by replacing f_{D1} and f_{D2} with each other.

The acquisition unit 24 acquires the transmission signals Tx1 and Tx2 output from the BBU 11. Then, the acquisition unit 24 outputs the acquired transmission signals Tx1 and Tx2 to the generation unit 22. The acquisition unit 24 is an example of a first acquisition unit. The generation unit 22 generates a cancellation signal Y of which frequency has been corrected based on the frequency errors estimated by the frequency error estimation unit 21, as a cancellation signal Y which is a replica of the PIM signal. The generation unit 22 includes a multiplier 220, a high-order term generation unit 221, a multiplier 222, and a compensation coefficient updating unit 223.

The multiplier 220 acquires the transmission signal Tx1 output from the BBU 11 via the acquisition unit 24 and corrects the frequency of the acquired transmission signal Tx1 based on the frequency error estimated by the frequency error estimation unit 21. Specifically, the multiplier 220 multiplies the transmission signal Tx1 by a correction signal corresponding to the frequency error estimated by the frequency error estimation unit 21. The multiplier 220 is, for example, a complex multiplier. The multiplier 220 is an example of a correction unit.

The high-order term generation unit 221 acquires the transmission signal Tx2 output from the BBU 11 via the acquisition unit 24. Then, the high-order term generation unit 221 generate a component Z of a high-order term to be included in the PIM signal according to, for example, the following calculation equation (1) based on the transmission signal Tx1 of which frequency has been corrected by the multiplier 220 and the transmission signal Tx2 acquired via the acquisition unit 24.

Z=Tx1·Tx1·conj(Tx2) (1)

In the calculation equation (1), conj(x) indicates a complex conjugate of x.

In this embodiment, the high-order term generation unit 221 calculates a third-order term component in the PIM signal as the component Z of the high-order term. However, as another example, the high-order term generation unit 221 may generate a component of a higher-order term than the third-order term in the PIM signal, as the component Z of the high-order term.

Specifically, for example, as illustrated in FIG. 3, the high-order term generation unit 221 includes multipliers 2210 and 2211, and a complex conjugate calculation unit 2212. The multiplier 2210 calculates a square of the transmission signal Tx1 of which frequency has been corrected by the multiplier 220. The complex conjugate calculation unit 2212 calculates a complex conjugate of the transmission signal Tx2 acquired via the acquisition unit 24. The multiplier 2211 multiplies the square of the transmission signal Tx1 calculated by the multiplier 2210, by the complex conjugate of the transmission signal Tx2 calculated by the complex conjugate calculation unit 2212, so as to generate the component Z of the high-order term in the PIM signal. The multipliers 2210 and 2211 are, for example, complex multipliers.

The compensation coefficient updating unit 223 sequentially updates a compensation coefficient A for compensating a phase and an amplitude of the cancellation signal according to, for example, the following calculation equation (2) by using the component Z of the high-order term calculated by the high-order term generation unit 221. In this embodiment, the compensation coefficient A is a coefficient of the third-order term in the PIM signal.

A=a+μ·conj(conj(Rx″)·Z) (2)

In the calculation equation (2), Rx″ is the reception signal Rx″ output from the combination unit 23 to be described later.

Specifically, for example, as illustrated in FIG. 3, the compensation coefficient updating unit 223 includes a delay unit 2230, a multiplier 2231, a complex conjugate calculation unit 2232, a complex conjugate calculation unit 2233, a multiplier 2234, and an adder 2235. The delay unit 2230 delays the component Z of the high-order term calculated by the high-order term generation unit 221, for a predetermined time. The complex conjugate calculation unit 2232 calculates the complex conjugate of the reception signal Rx″ output from the combination unit 23. The multiplier 2231 multiplies the component Z of the high-order term delayed by the delay unit 2230, by the complex conjugate of the reception signal Rx″ calculated by the complex conjugate calculation unit 2232.

The complex conjugate calculation unit 2233 calculates the complex conjugate of the multiplication result by the multiplier 2231. The multiplier 2234 multiplies the complex conjugate of the multiplication result by the multiplier 2231, by a step coefficient μ. The adder 2235 adds the multiplication result by the multiplier 2234 to the compensation coefficient A prior to the updating, so as to update the compensation coefficient A. The updated compensation coefficient A is output to the multiplier 222. The multipliers 2231 and 2234 are, for example, complex multipliers.

The multiplier 222 multiplies the component Z of the high-order term of the PIM signal which has been output from the high-order term generation unit 221, by the compensation coefficient A updated by the compensation coefficient updating unit 223, so as to generate the cancellation signal Y. The generated cancellation signal Y is output to the combination unit 23. The multiplier 222 is, for example, a complex multiplier. The multiplier 222 is an example of a cancellation signal generation unit.

The acquisition unit 25 acquires the reception signal Rx′ down-converted to the baseband by the RRH 30. Then, the acquisition unit 25 outputs the acquired reception signal Rx′ to the combination unit 23. The acquisition unit 25 is an example of a second acquisition unit.

The combination unit 23 subtracts the cancellation signal Y output from the multiplier 222, from the reception signal Rx′ output from the acquisition unit 25, so as to reduce the PIM signal included in the reception signal Rx′. Specifically, the combination unit 23 inverts the cancellation signal Y output from the multiplier 222 and combines the inverted cancellation signal Y with the reception signal Rx′ output from the acquisition unit 25. Then, the combination unit 23 outputs the combined reception signal Rx″ to the compensation coefficient updating unit 223 and the BBU 11.

The frequency error estimation unit 21 estimates the frequency errors of the transmission signal Tx1 up-converted by the local oscillation signal generation unit 32 in the RRH 30-1 and the transmission signal Tx2 up-converted by the local oscillation signal generation unit 32 in the RRH 30-2. The frequency error estimation unit 21 includes a frequency shift amount calculation unit 210 and a phase shift amount calculation unit 211. The phase shift amount calculation unit 211 calculates a phase shift amount of the compensation coefficient A by referring to the compensation coefficient A sequentially updated by the compensation coefficient updating unit 223. Specifically, the phase shift amount calculation unit 211 refers to the compensation coefficient A sequentially updated by the compensation coefficient updating unit 223 at each predetermined time T_{S}, and calculates a phase shift amount of the compensation coefficient A according to, for example, the following calculation equation (3). Then, the phase shift amount calculation unit 211 outputs the calculated phase shift amount to the frequency shift amount calculation unit 210.

Δ∠A₃(n)=∠A₃(nT_{S})−∠A₃((n−1)T_{S}) (3)

In the calculation equation (3), ∠A₃(nT_{S}) indicates a phase of an n^{th} third-order compensation coefficient A, and Δ∠A₃(n) indicates a phase shift amount between the phase of the n^{th} third-order compensation coefficient A and a phase of an n−1^{th} third-order compensation coefficient A.

The predetermined time T_{S} is a time during which the phase of the compensation coefficient A changing depending on a frequency error may be measured multiple times, in a time until the phase of the compensation coefficient A is rotated by 360°. Specifically, when the frequency error is, for example, several Hz, the predetermined time T_{S} is set to, for example, about several tens of milliseconds.

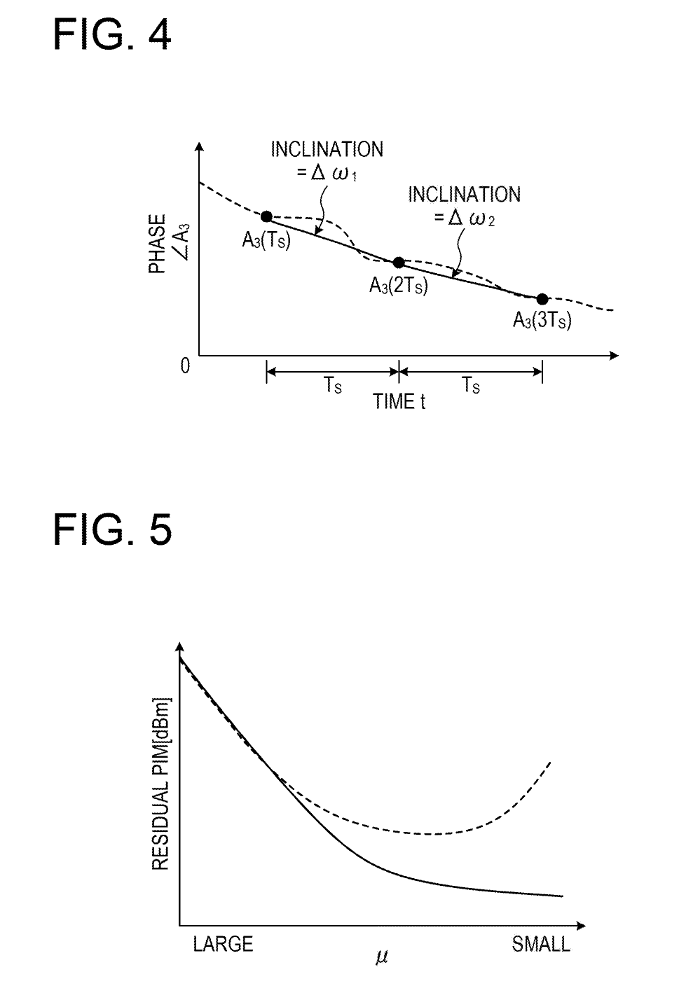

Here, when the frequency of the PIM signal included in the reception signal Rx″ and the frequency of the cancellation signal Y generated by the multiplier 222 are identical to each other, the phase of the compensation coefficient A does not change. However, when a frequency error exists between the PIM signal included in the reception signal Rx″ and the cancellation signal Y generated by the multiplier 222, the phase of the compensation coefficient A changes with elapse of time as illustrated in, for example, FIG. 4. FIG. 4 is a view for explaining an example of a frequency error estimating method according to First Embodiment. The larger the frequency error between the PIM signal included in the reception signal Rx″ and the cancellation signal Y generated by the multiplier 222, the larger the phase shift amount of the compensation coefficient A per unit time. In this embodiment, for example, as illustrated in FIG. 4, the phase shift amount of the compensation coefficient A per unit time is calculated as a frequency error Δωₙ.

Considering the PIM component of 2f_{D1}−f_{D2}, the compensation coefficient A of a third-order component is expressed as Tx1·Tx1·Conj(Tx2), and the compensation coefficient A of a fifth- or higher-order component is expressed in a form of a multiplication of Tx1·Tx1·Conj(Tx2) by a real number. Thus, the frequency error may be calculated by using the compensation coefficient A of a third-order component. In addition, of compensation coefficients of odd-numbered order components, the magnitude of the third-order compensation coefficient is the largest. Thus, in this embodiment, the frequency error is calculated by using the third-order compensation coefficient. As a result, the frequency error may be accurately calculated.

The frequency shift amount calculation unit 210 calculates the frequency error based on the phase shift amount calculated by the phase shift amount calculation unit 211. Specifically, the frequency shift amount calculation unit 210 calculates the frequency error Δωₙ according to, for example, the following calculation equation (4).

$${Δω}_{n} = \frac{Δ∠ {A}_{3} ( n )}{{T}_{s}} \qquad ( 4 )$$

Then, the frequency shift amount calculation unit 210 calculates the frequency shift amount ωₙ of a correction signal “s” based on, for example, the following calculation equation (5).

$${ω}_{n} = \frac{{Δω}_{n}}{2} \qquad ( 5 )$$

Then, the frequency shift amount calculation unit 210 generates the correction signal “s” based on, for example, the following calculation equation (6), and outputs the generated correction signal “s” to the multiplier 220.

s=e^{jω}^{ₙ}^{t} (6)

In addition, the frequency shift amount calculation unit 210 may calculate the frequency shift amount ωₙ of the correction signal “s” based on, for example, the following calculation equation (7), rather than the calculation equation (5) described above. In addition, an initial value ω₀ of the frequency shift amount ωₙ is, for example,0.

ωₙ=ωₙ₋₁+γΔωₙ (7)

In the calculation equation (7), γ is a step size parameter, and for example, a value of 0.5 may be used. In addition, the frequency shift amount calculation unit 210 may calculate ½ of a moving average of the frequency error Δωₙ as the frequency shift amount ωₙ of the correction signal “s.”

Here, when the value of the step coefficient μ set in the compensation coefficient updating unit 223 is small, the residual PIM included in the reception signal Rx″ with which the cancellation signal Y has been combined becomes small, as illustrated in, for example, FIG. 5. FIG. 5 is a view illustrating an example of a change of the residual PIM.

However, when the replica of the PIM signal corresponding to the frequency of 2f_{D1}−f_{D2} is generated without considering the error of the local oscillation signal of each RRH 30, a certain amount of the PIM signal remains in the combined reception signal Rx″ as indicated, for example, by the dashed line in FIG. 5, even though the step coefficient μ is small.

As in this embodiment, when the frequency of the cancellation signal is corrected based on the frequency error estimated based on the phase shift amount of the compensation coefficient A, the PIM signal remaining in the reception signal Rx″ is reduced as the step coefficient μ becomes small, as indicated, for example, by the solid line in FIG. 5. Thus, the quality of the reception signal Rx″ may be improved.

<Processes by Communication Device 10>

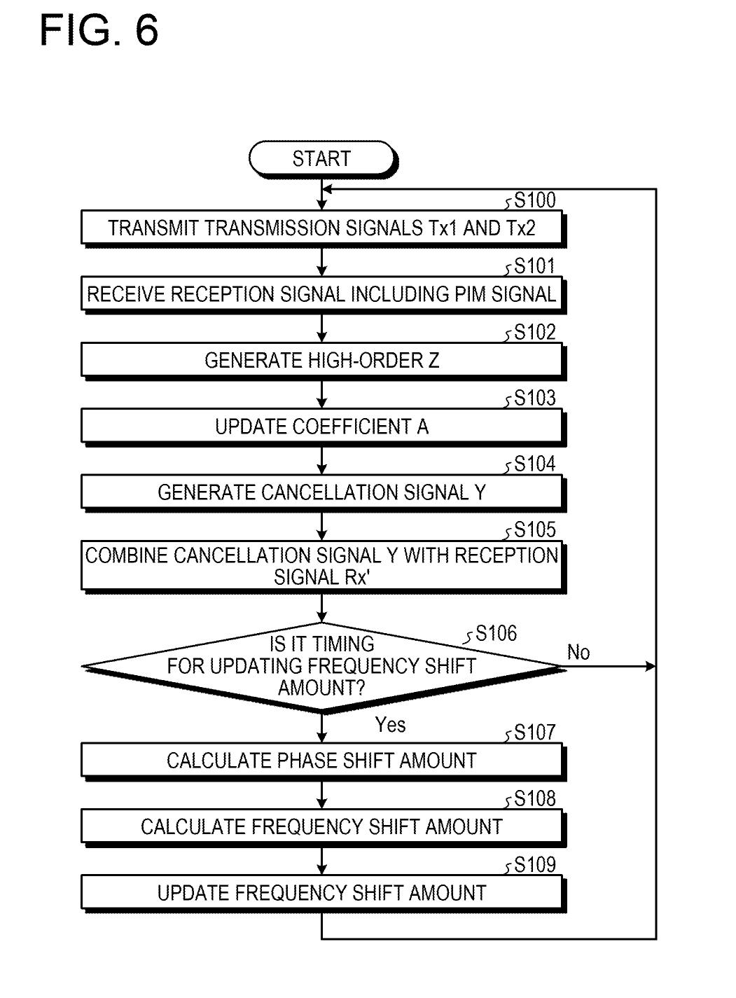

FIG. 6 is a flowchart illustrating an example of the processes performed by the communication device 10 according to First Embodiment. The communication device 10 performs the processes illustrated in the flowchart of FIG. 6 at each predetermined timing.

First, the BBU 11 outputs the transmission signal Tx1 to each of the cancellation devices 20 and the RRH 30-1. The transmission signal Tx1 is up-converted to the frequency of f_{D1}+Δf_{D1} by the RRH 30-1 and transmitted from the antenna 300 (S100). Further, the BBU 11 outputs the transmission signal Tx2 to each of the cancellation devices 20 and the RRH 30-2. The transmission signal Tx2 is up-converted to the frequency of f_{D2}+Δf_{D2} by the RRH 30-2 and transmitted from the antenna 300 (S100).

Next, each RRH 30 receives a reception signal including a PIM signal via the antenna 300 (S101), and down-converts the received reception signal with the frequency of the RF band to the frequency of the baseband. Then, the RRH 30-1 converts the reception signal down-converted to the frequency of the baseband, into a digital signal, and outputs the converted reception signal Rx1′ to the cancellation device 20-1. In addition, the RRH 30-2 converts the reception signal down-converted to the frequency of the baseband, into a digital signal, and outputs the converted reception signal Rx2′ to the cancellation device 20-2.

Next, the multiplier 220 of each cancellation device 20 corrects the frequency of the transmission signal Tx1 output from the BBU 11, based on the correction signal “s” corresponding to the frequency error estimated by the frequency error estimation unit 21. In the initial state, the correction signal “s” corresponding to a frequency error of 0, that is, the correction signal “s” when the frequency shift amount ωₙ in the calculation equation (6) above is 0 is input from the frequency error estimation unit 21 to the multiplier 220.

The high-order term generation unit 221 of each cancellation device 20 generates the component Z of the high-order term in the PIM signal according to, for example, the calculation equation (1) described above, by using the transmission signal Tx1 of which frequency has been corrected by the multiplier 220 and the transmission signal Tx2 output from the BBU 11 (S102).

Next, the compensation coefficient updating unit 223 of each cancellation device 20 updates the compensation coefficient A for compensating the phase and amplitude of the cancellation signal according to, for example, the calculation equation (2) described above, by using the component Z of the high-order term calculated by the high-order term generation unit 221 (S103).

Next, the multiplier 222 of each cancellation device 20 multiplies the component Z of the high-order term in the PIM signal which has been output from the high-order term generation unit 221, by the compensation coefficient A updated by the compensation coefficient updating unit 223, so as to generate the cancellation signal Y (S104).

Next, the combination unit 23 of each cancellation device 20 combines the cancellation signal Y output from the multiplier 222 with the reception signal Rx′ output from the RRH 30 (S105). The combined reception signal Rx″ is output to the compensation coefficient updating unit 223 and the BBU 11.

Next, the phase shift amount calculation unit 211 of each cancellation device 20 determines whether it is a timing for updating the frequency shift amount (S106). The frequency error estimation unit 21 updates the frequency shift amount at each predetermined time T_{S} (e.g., every several tens of milliseconds). When it is determined that it is not a timing for updating the frequency shift amount (S106: “No”), the BBU 11 performs the process of the operation S100 again.

Meanwhile, when it is determined that it is a timing for updating the frequency shift amount (S106: “Yes”), the phase shift amount calculation unit 211 calculates the phase shift amount of the compensation coefficient A according to, for example, the calculation equation (3) described above, by using the compensation coefficient A updated by the compensation coefficient updating unit 223 (S107). Then, the phase shift amount calculation unit 211 outputs the calculated phase shift amount to the frequency shift amount calculation unit 210.

Next, the frequency shift amount calculation unit 210 calculates the frequency error Δωₙ according to, for example, the calculation equation (4) described above, based on the phase shift amount calculated by the phase shift amount calculation unit 211. Then, the frequency shift amount calculation unit 210 calculates the frequency shift amount ωₙ of the correction signal “s” based on, for example, the calculation equation (5) described above (S108). Then, the frequency shift amount calculation unit 210 updates the frequency shift amount ωₙ of the correction signal “s” according to, for example, the calculation equation (6) described above, by using the calculated frequency shift amount ωₙ (S109). The correction signal “s” of which frequency shift amount ωₙ has been updated is output to the multiplier 220. Then, the BBU 11 performs the process of the operation S100 again.

The order of the processes of the operations S100 to S109 described above is not limited to that in the flowchart of FIG. 6. For example, the operations S100 and S101, the operations S102 to S105, and the operations S106 to S109 may be independently performed.

<Another Example of Cancellation Device 20 According to First Embodiment>

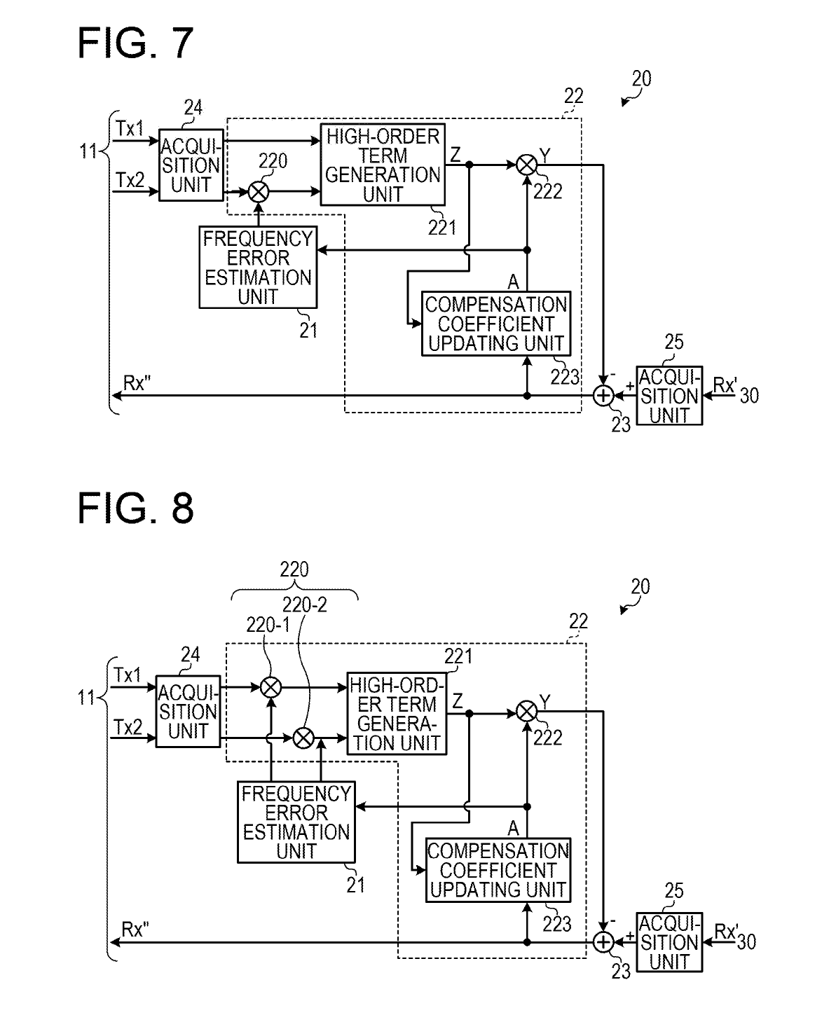

In First Embodiment described above, the multiplier 220 corrects the frequency of the transmission signal Tx1 output from the BBU 11 based on the correction signal corresponding to the frequency error estimated by the frequency error estimation unit 21. However, the present disclosure is not limited thereto. As another example, as illustrated in FIGS. 7 to 11, for example, the multiplier 220 may correct the frequency of another signal within the cancellation device 20 based on the correction signal corresponding to the frequency error estimated by the frequency error estimation unit 21. FIGS. 7 to 11 are block diagrams illustrating another example of the cancellation device 20 according to First Embodiment.

For example, as illustrated in FIG. 7, the multiplier 220 acquires the transmission signal Tx2 output from the BBU 11 via the acquisition unit 24. Then, the multiplier 220 may correct the frequency of the acquired transmission signal Tx2 based on the correction signal corresponding to the frequency error estimated by the frequency error estimation unit 21. In this case, the high-order term generation unit 221 acquires the transmission signal Tx1 output from the BBU 11 via the acquisition unit 24, and generates the component Z of the high-order term by using the acquired transmission signal Tx1 and the transmission signal Tx2 of which frequency has been corrected by the multiplier 220. In the example illustrated in FIG. 7, when the PIM signal with the frequency of 2f_{D1}-f_{D2} is canceled, the frequency error estimation unit 21 applies the frequency error Δωₙ as it is to the frequency shift amount ωₙ, and generates the correction signal “s” based on the equation (6) described above.

In addition, for example, as illustrated in FIG. 8, the multiplier 220 may include multipliers 220-1 and 220-2. The multiplier 220-1 acquires the transmission signal Tx1 output from the BBU 11 via the acquisition unit 24, and the multiplier 220-2 acquires the transmission signal Tx2 output from the BBU 11 via the acquisition unit 24. Then, the multiplier 220-1 corrects the frequency of the acquired transmission signal Tx1 based on the correction signal corresponding to the frequency error estimated by the frequency error estimation unit 21. In addition, the multiplier 220-2 corrects the frequency of the acquired transmission signal Tx2 based on the correction signal corresponding to the frequency error estimated by the frequency error estimation unit 21.

In the example illustrated in FIG. 8, when the PIM signal with the frequency of 2f_{D1}−f_{D2} is canceled, the frequency error estimation unit 21 calculates ¼ of the frequency error Δωₙ as the frequency shift amount ωₙ for the transmission signal Tx1, and calculates ½ of the frequency error Δωₙ as the frequency shift amount ωₙ for the transmission signal Tx2. Then, the frequency error estimation unit 21 generates the correction signal “s” for each of the transmission signals Tx1 and Tx2 based on the equation (6) described above. Then, the frequency error estimation unit 21 outputs the correction signal “s” generated for the transmission signal Tx1 to the multiplier 220-1, and outputs the correction signal “s” generated for the transmission signal Tx2 to the multiplier 220-2.

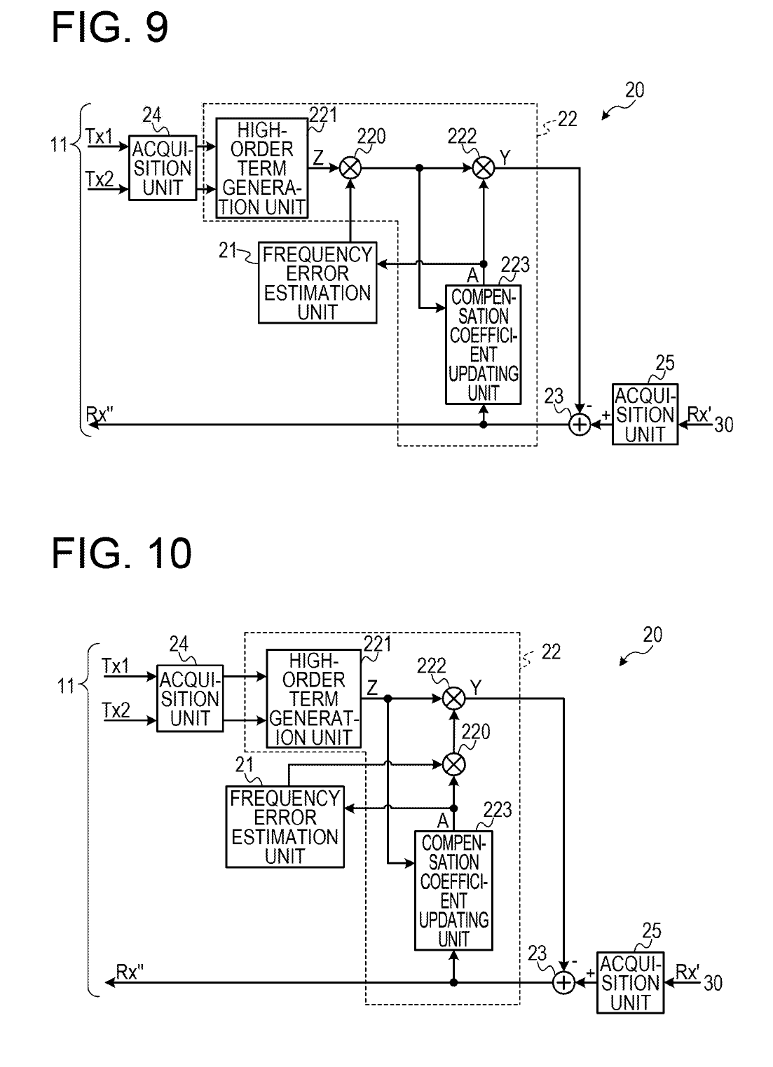

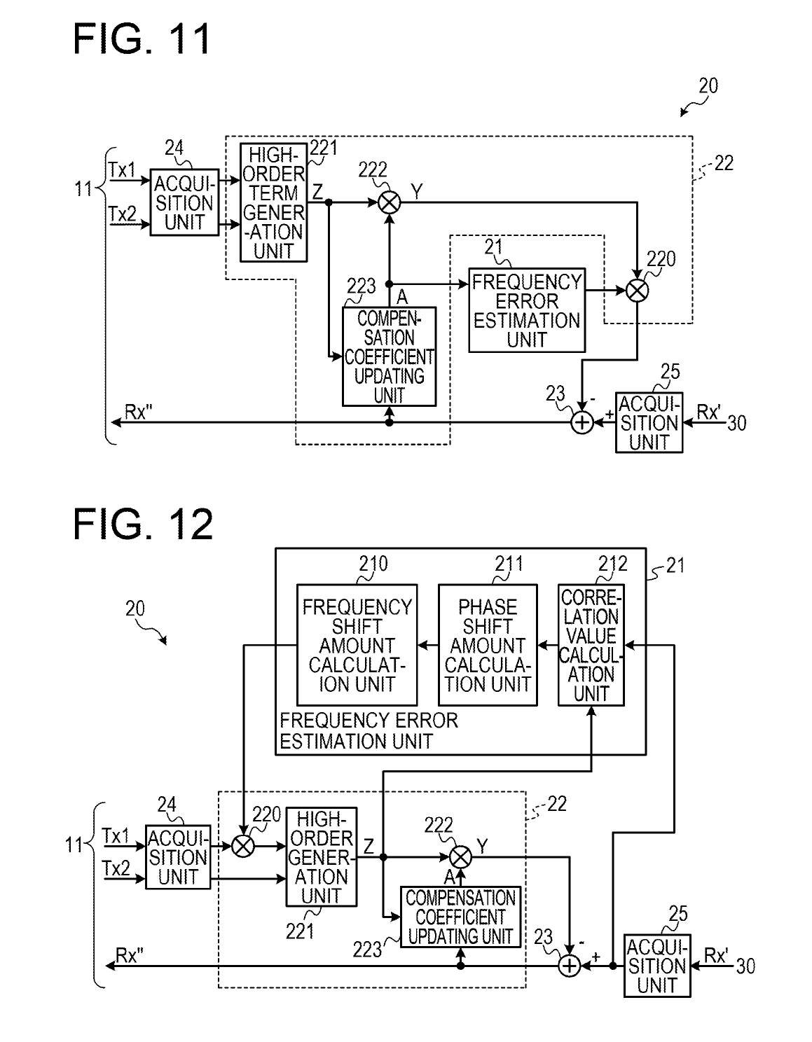

In addition, for example, as illustrated in FIG. 9, the multiplier 220 may correct the frequency of the component Z of the high-order term generated by the high-order term generation unit 221, based on the correction signal corresponding to the frequency error estimated by the frequency error estimation unit 21. In addition, for example, as illustrated in FIG. 10, the multiplier 220 may correct the frequency of the compensation coefficient A updated by the compensation coefficient updating unit 223, based on the correction signal corresponding to the frequency error estimated by the frequency error estimating unit 21. In addition, for example, as illustrated in FIG. 11, the multiplier 220 may correct the frequency of the cancellation signal Y generated by the multiplier 220, based on the correction signal corresponding to the frequency error estimated by the frequency error estimation unit 21. In the examples illustrated in FIGS. 9 to 11, when the PIM signal with the frequency of 2f_{D1}−f_{D2} is canceled, the frequency error estimation unit 21 applies the frequency error Δωₙ as it is to the frequency shift amount ωₙ, and generates the correction signal “s” based on the equation (6) described above.

<Effects of First Embodiment>

First Embodiment has been described. According to this embodiment, the communication device 10 includes the RRH 30-1, the RRH 30-2, the frequency error estimation unit 21, the generation unit 22, and the combination unit 23. The RRH 30-1 up-converts the transmission signal Tx1 to the frequency f_{D1}+Δf_{D1} and transmits the up-converted transmission signal Tx1. The RRH 30-2 up-converts the transmission signal Tx2 to the frequency f_{D2}+Δf_{D2} which is different from the frequency f_{D1}+Δf_{D1}, and transmits the up-converted transmission signal Tx2. In addition, the RRH 30-1 and the RRH 30-2 receive a reception signal including a PIM signal generated by the up-converted transmission signals Tx1 and Tx2, and down-convert the reception signal to the baseband. The frequency error estimation unit 21 estimates the frequency errors of the up-converted transmission signals Tx1 and Tx2. The generation unit 22 generates the cancellation signal Y of which frequency has been corrected based on the frequency error estimated by the frequency error estimation unit 21, by using the transmission signals Tx1 and Tx2, as the cancellation signal Y which is a replica of the PIM signal. The combination unit 23 combines the cancellation signal with the reception signal down-converted by the RRH 30-1 or 30-2. As a result, the communication device 10 of the present embodiment may improve the quality of the reception signal.

In addition, in the embodiment described above, the generation unit 22 includes the multiplier 220, the high-order term generation unit 221, the multiplier 222, and the compensation coefficient updating unit 223. The high-order term generation unit 221 generates a component of a high-order term included in the cancellation signal based on the transmission signals Tx1 and Tx2. The compensation coefficient updating unit 223 sequentially updates the coefficient applied to the component of the high-order term, based on the component of the high-order term generated by the high-order term generation unit 221 and the reception signal down-converted by the RRH 30-1 or the RRH 30-2. The multiplier 222 generates the cancellation signal by applying the coefficient updated by the compensation coefficient updating unit 223 to the component of the high-order term generated by the high-order term generation unit 221. The multiplier 220 corrects the frequency of the signal used for generating the cancellation signal based on the frequency error estimated by the frequency error estimation unit 21. The frequency error estimation unit 21 estimates the frequency error based on a phase change of the coefficient sequentially updated by the compensation coefficient updating unit 223. As a result, the communication device 10 of the present embodiment may improve the quality of the reception signal.

In the embodiment described above, the frequency error estimation unit 21 estimates the frequency error by using a coefficient corresponding to a third-order component among the coefficients sequentially updated by the compensation coefficient updating unit 223. As a result, the communication device 10 of the present embodiment may accurately estimate the frequency error.

In the embodiment described above, the multiplier 220 may correct the frequency of at least one of the transmission signals Tx1 and Tx2 input to the high-order term generation unit 221, based on the frequency error estimated by the frequency error estimation unit 21. As a result, the communication device 10 of the present embodiment may improve the quality of the reception signal.

In the embodiment described above, the multiplier 220 may correct the frequency of any one of the component Z of the high-order term generated by the high-order term generation unit 221, the coefficient updated by the compensation coefficient updating unit 223, and the cancellation signal Y generated by the multiplier 222, based on the frequency error estimated by the frequency error estimation unit 21. As a result, the communication device 10 of the present embodiment may improve the quality of the reception signal.

### Second Embodiment

In First Embodiment described above, the frequency errors of the transmission signal Tx1 up-converted by the RRH 30-1 and the transmission signal Tx2 down-converted by the RRH 30-2 are estimated based on the phase shift amount of the compensation coefficient A updated by the compensation coefficient updating unit 223. In Second Embodiment, a correlation value between the reception signal Rx′ down-converted to the baseband and the component Z of the high-order term generated by the high-order term generation unit 221 is calculated. Then, based on the calculated correlation value, the frequency errors of the transmission signal Tx1 up-converted by the RRH 30-1 and the transmission signal Tx2 up-converted by the RRH 30-2 are estimated. Hereinafter, descriptions will be made focusing on differences from First Embodiment. Since the configuration of the communication device 10 of Second Embodiment is the same as that of the communication device 10 of First Embodiment described using FIG. 1, detailed descriptions thereof will be omitted.

<Cancellation Device 20>

FIG. 12 is a block diagram illustrating an example of a cancellation device 20 according to Second Embodiment. In the present embodiment, the cancellation device 20 includes the frequency error estimation unit 21, the generation unit 22, and the combination unit 23. In FIG. 12, the blocks denoted by the same reference numerals as used in FIG. 3 have the same or similar functions to those of the blocks in FIG. 3, except for the points to be described hereinbelow, and thus, detailed descriptions thereof will be omitted.

In the present embodiment, the frequency error estimation unit 21 includes the frequency shift amount calculation unit 210, the phase shift amount calculation unit 211, and a correlation value calculation unit 212. The correlation value calculation unit 212 calculates a correlation value Cor(n) between the reception signal Rx′ down-converted to the baseband by the RRH 30 and the component Z of the high-order term generated by the high-order term generation unit 221. Specifically, the correlation value calculation unit 212 calculates the correlation value Cor(n) between the reception signal Rx′ and the component Z of the high-order term at each predetermined time T_{S} by using, for example, the following calculation equation (8).

$$Cor ( n ) = {\sum }_{t = {nT}_{s}}^{{nT}_{s} + {t}_{0}} {Rx}^{′} ( t ) \cdot conj ( Z ( t ) ) \qquad ( 8 )$$

In the present embodiment, the correlation value calculation unit 212 calculates the correlation value Cor(n) with the reception signal Rx′ of the baseband by using a component of a third-order term in the component Z of the high-order term generated by the high-order term generation unit 221. Among the odd-numbered order components of the PIM signal included in the reception signal Rx′ of the baseband, a third-order term component is the largest. Thus, when the correlation value Cor(n) with the reception signal Rx′ of the baseband is calculated by using the component of the third-order term in the component Z of the high-order term generated by the high-order term generation unit 221, the calculation value Cor(n) may be accurately calculated while suppressing the amount of calculation.

The phase shift amount calculation unit 211 calculates the phase shift amount of the correlation value Cor(n) based on the correlation value Cor(n) calculated by the correlation value calculation unit 212. Specifically, the phase shift amount calculation unit 211 calculates a phase shift amount Δ∠Cor(n) of the correlation value Cor(n) at each predetermined time Tₛ according to, for example, the following calculation equation (9) by using the correlation value Cor(n) calculated by the correlation value calculation unit 212. Then, the phase shift amount calculation unit 211 outputs the calculated phase shift amount Δ∠Cor(n) to the frequency shift amount calculation unit 210.

Δ∠Cor(n)=∠Cor(n)−∠Cor(n−1) (9)

In the calculation equation (9), ∠Cor(n) indicates the phase of an nth correlation value Cor(n), and Δ∠Cor(n) indicates the phase shift amount between the phase of the nth correlation value Cor(n) and the phase of an n−1th correlation value Cor(n).

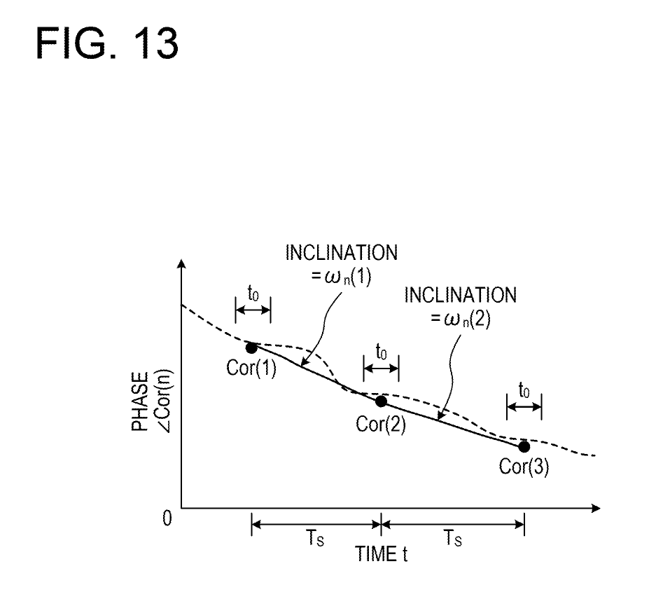

Here, when the frequency of the PIM signal included in the reception signal Rx″ and the frequency of the cancellation signal Y generated by the multiplier 222 are identical to each other, the phase of the correlation value Cor(n) does not change. However, when a frequency error exists between the PIM signal included in the reception signal Rx″ and the cancellation signal Y generated by the multiplier 222, the phase of the correlation value Cor(n) changes with elapse of time, for example, as illustrated in FIG. 13. FIG. 13 is a view for explaining an example of a frequency error estimating method according to Second Embodiment. The larger the frequency error between the PIM signal included in the reception signal Rx″ and the cancellation signal generated by the multiplier 222, the larger the phase shift amount of the correlation value Cor(n) per unit time. In the present embodiment, for example, as illustrated in FIG. 13, the phase shift amount of the correlation value Cor(n) per unit time is calculated as the frequency error Δωₙ.

The frequency shift amount calculation unit 210 calculates the frequency error based on the phase shift amount Δ∠Cor(n) of the correlation value Cor(n) calculated by the phase shift amount calculation unit 211. Specifically, the frequency shift amount calculation unit 210 calculates the frequency error Δωₙ according to, for example, the following calculation equation (10).

$${Δω}_{n} = \frac{Δ∠ Cor ( n )}{{T}_{s}} \qquad ( 10 )$$

Then, the frequency shift amount calculation unit 210 calculates the frequency shift amount ωₙ of the correction signal “s” based on, for example, the calculation equation (5) described above, and generates the correction signal “s” based on, for example, the calculation equation (6) described above by using the calculated frequency shift amount ωₙ. Then, the frequency shift amount calculation unit 210 outputs the generated correction signal “s” to the multiplier 220. In the present embodiment as well, the frequency shift amount calculation unit 210 may calculate the frequency shift amount ωₙ of the correction signal “s” based on, for example, the calculation equation (7) described above, rather than the calculation equation (5) described above. In addition, in the present embodiment as well, the frequency shift amount calculation unit 210 may calculate ½ of the moving average of the frequency error Δωₙ as the frequency shift amount ωₙ of the correction signal “s.”

In addition, in the present embodiment, the multiplier 220 corrects the frequency of the transmission signal Tx1 based on the correction signal “s” corresponding to the frequency error estimated by the frequency error estimation unit 21. However, the present disclosure is not limited thereto. The multiplier 220 may correct a frequency of another signal within the cancellation device 20 based on the correction signal “s” corresponding to the frequency error estimated by the frequency error estimation unit 21, as in the another example of First Embodiment which is illustrated in each of FIGS. 7 to 11.

<Effects of Second Embodiment>

Second Embodiment has been described. In this embodiment, the frequency error estimation unit 21 estimates the frequency error based on a phase change of the correlation value between the reception signal Rx′ down-converted by the RRH 30 and the component Z of the high-order term generated by the high-order term generation unit 221. As a result, the communication device 10 of the present embodiment may improve the quality of the reception signal.

In addition, in Second Embodiment described above, the frequency error estimation unit 21 calculates the correlation value by using a third-order component in the component Z of the high-order term generated by the high-order term generation unit 221. As a result, the frequency error estimation unit 21 may accurately calculate the correlation value between the reception signal Rx′ down-converted by the RRH 30 and the component Z of the high-order term generated by the high-order term generation unit 221.

### Third Embodiment

In First Embodiment described above, the transmission signal Tx1 up-converted to the frequency of f_{D1}+Δf_{D1} is transmitted from the RRH 30-1, and the transmission signal Tx2 up-converted to the frequency of f_{D2}+Δf_{D2} is transmitted from the RRH 30-2. In present Third Embodiment, the RRH 30-1 up-converts each of the two transmission signals Tx11 and Tx12 to the frequency of f_{D1}+Δf_{D1} and transmits the transmission signals from separate antennas, respectively. Further, in present Third Embodiment, the RRH 30-2 up-converts each of the two transmission signals Tx21 and Tx22 to the frequency of f_{D2}+Δf_{D2} and transmits the transmission signals from separate antennas, respectively. That is, in this embodiment, the RRH 30-1 and the RRH 30-2 transmit the four transmission signals Tx11 to Tx22 by multi-antennas. The transmission signal Tx11 is an example of a first transmission signal, the transmission signal Tx12 is an example of a third transmission signal, the transmission signal Tx21 is an example of a second transmission signal, and the transmission signal Tx12 is an example of a fourth transmission signal.

<Communication Device 10>

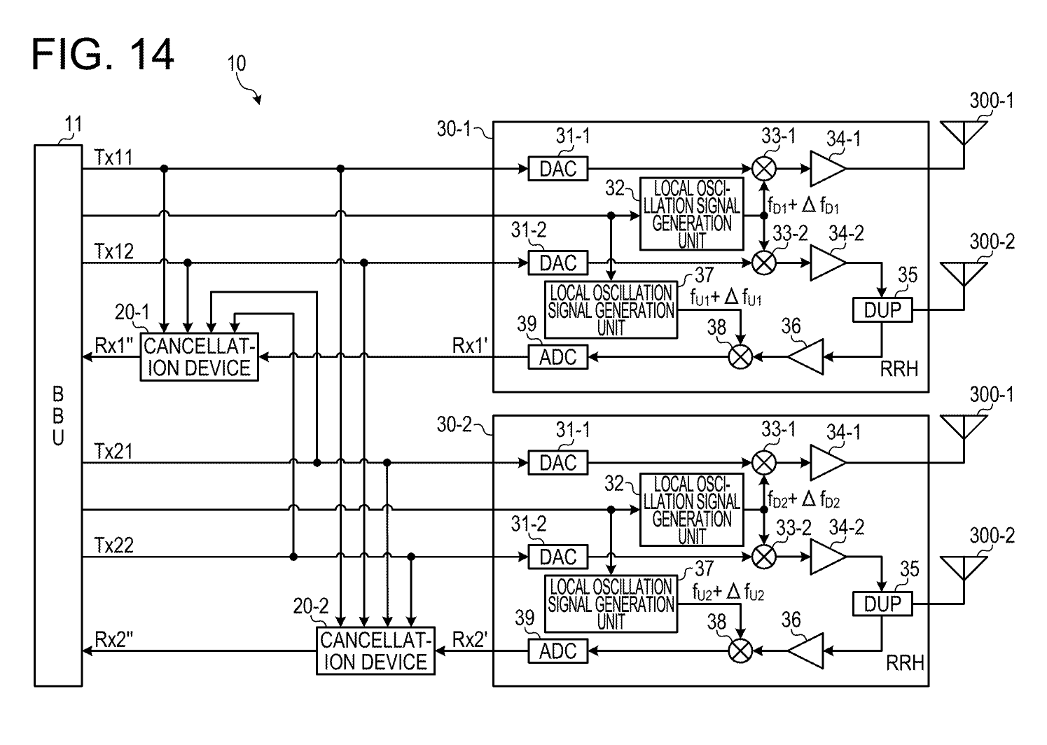

FIG. 14 is a block diagram illustrating an example of a communication device 10 according to Third Embodiment. The communication device 10 includes the BBU 11, the cancellation devices 20-1 and 20-2, and the RRHs 30-1 and 30-2. Each RRH 30 includes the DACs 31-1 and 31-2, the local oscillation signal generation unit 32, the up-converters 33-1 and 33-2, the PAs 34-1 and 34-2, and the DUP 35. Further, each RRH 30 includes the LNA 36, the local oscillation signal generation unit 37, the down-converter 38, the ADC 39, and the antennas 300-1 and 300-2. In FIG. 14, the blocks denoted by the same reference numerals as used in FIG. 1 have the same or similar functions to those of the blocks in FIG. 1, except for the points to be described hereinbelow, and thus, descriptions thereof will be omitted.

In the RRH 30-1, the local oscillation signal generation unit 32 generates the local oscillation signal of the frequency f_{D1}+Δf_{D1} by using the frequency of a reference signal output from the BBU 11. In addition, the local oscillation signal generation unit 37 generates the local oscillation signal of the frequency f_{U1}+Δf_{U1} by using the frequency of the reference signal output from the BBU 11. In the RRH 30-1 of the present embodiment, the local oscillation signal generation units 32 and 37 generate the local oscillation signals, respectively, by commonly using the frequency of the reference signal output from the BBU 11 as a reference.

Similarly, in the RRH 30-2 as well, the local oscillation signal generation unit 32 generates the local oscillation signal of the frequency f_{D2}+Δf_{D2} by using a frequency of a reference signal output from the BBU 11. In addition, the local oscillation signal generation unit 37 generates the local oscillation signal of the frequency f_{U2}+Δf_{U12} by using the frequency of a reference signal output from the BBU 11. In the RRH 30-2 of the present embodiment, the local oscillation signal generation units 32 and 37 generate the local oscillation signals, respectively, by commonly using the frequency of the reference signal output from the BBU 11 as a reference.

In the RRH 30-1, the DAC 31-1 converts the transmission signal Tx11 output from the BBU 11, from a digital signal into an analog signal and outputs the converted transmission signal Tx11 to the up-converter 33-1. The up-converter 33-1 up-converts the transmission signal Tx11 of the baseband which has been converted into the analog signal by the DAC 31-1, to the frequency of the RF band by the local oscillation signal of the frequency f_{D1}+Δf_{D1} output from the local oscillation signal generation unit 32. The PA 34-1 amplifies the transmission signal Tx11 up-converted by the up-converter 33-1. The antenna 300-1 radiates the transmission signal Tx11 amplified by the PA 34-1 into the space.

In the RRH 30-1, the DAC 31-2 converts the transmission signal Tx12 output from the BBU 11, from a digital signal into an analog signal, and outputs the converted transmission signal Tx12 to the up-converter 33-2. The up-converter 33-2 up-converts the transmission signal Tx12 of the baseband which has been converted into the analog signal by the DAC 31-2, to the frequency of the RF band by the local oscillation signal of the frequency f_{D1}+Δf_{D1} output from the local oscillation signal generation unit 32. The PA 34-2 amplifies the transmission signal Tx12 up-converted by the up-converter 33-2. The DUP 35 causes the transmission signal Tx12 amplified by the PA 34-2 to pass through the antenna 300-2. The antenna 300-2 radiates the transmission signal Tx12 passing through the DUP 35 into the space.

In the RRH 30-2, the DAC 31-1 converts the transmission signal Tx21 output from the BBU 11, from a digital signal into an analog signal, and outputs the converted transmission signal Tx21 to the up-converter 33-1. The up-converter 33-1 up-converts the transmission signal Tx21 of the baseband which has been converted into the analog signal by the DAC 31-1, to the frequency of the RF band by the local oscillation signal of the frequency f_{D2}+Δf_{D2} output from the local oscillation signal generation unit 32. The PA 34-1 amplifies the transmission signal Tx21 up-converted by the up-converter 33-1. The antenna 300-1 radiates the transmission signal Tx21 amplified by the PA 34-1 into the space.

In the RRH 30-2, the DAC 31-2 converts the transmission signal Tx22 output from the BBU 11, from a digital signal into an analog signal and outputs the converted transmission signal Tx22 to the up-converter 33-2. The up-converter 33-2 up-converts the transmission signal Tx22 of the baseband which has been converted into the analog signal by the DAC 31-2, to the frequency of the RF band by the local oscillation signal of the frequency f_{D2}+Δf_{D2} output from the local oscillation signal generation unit 32. The PA 34-2 amplifies the transmission signal Tx22 up-converted by the up-converter 33-2. The DUP 35 causes the transmission signal Tx22 amplified by the PA 34-2 to pass through the antenna 300-2. The antenna 300-2 radiates the transmission signal Tx22 passing through the DUP 35 into the space.

In the present embodiment, the reception signal Rx′ output from the RRH 30 to the cancellation device 20 includes a PIM signal S_{PIM} represented in the following equation (11). The PIM signal S_{PIM} represented in the equation (11) below indicates a component corresponding to 2f_{D1}−f_{D2}.

S_{PIM}=A₃₁·Tx11·Tx11·conj(Tx21)

+A₃₂·Tx11·Tx11·conj(Tx22)

+A₃₃·Tx11·Tx11·conj(Tx21)

+A₃₄·Tx11·Tx11·conj(Tx22)

+A₃₅·Tx11·Tx11·conj(Tx21)

+A₃₆·Tx11·Tx11·conj(Tx22) (11)

In the equation (11), A₃₁ to A₃₆ indicate compensation coefficients of the respective terms. As represented in the equation (11), the PIM signal S_{PIM} includes six terms.

The generation unit 22 in the cancellation device 20 generates the cancellation signal Y corresponding to the equation (11) above. The combination unit 23 in the cancellation device 20 combines the cancellation signal Y with the reception signal Rx′ so as to eliminate the PIM signal included in the reception signal Rx′.

In addition, the frequency error estimation unit 21 in the cancellation device 20 estimates a frequency error Δωₙ based on the phase shift amounts of the compensation coefficients of the respective terms included in the equation (11) above. For example, the frequency error estimation unit 21 calculates frequency errors Δωn based on the compensation coefficients of the six respective terms included in the equation (11) above, and calculates an average value of the plurality of calculated frequency errors Δωₙ as an estimated value of the frequency error Δωₙ. In addition, the frequency error estimation unit 21 may estimate the frequency error Δωₙ based on the phase shift amount of the compensation coefficient of one of the six terms included in the equation (11) above. For example, the frequency error estimation unit 21 may compare the magnitudes (scalars) of the values of the compensation coefficients of the six terms included in the equation (11) above with each other, and may estimate the frequency error Δωₙ by using the compensation coefficient having the largest value. As a result, the frequency error Δωₙ may be accurately estimated.

Then, the frequency error estimation unit 21 generates the correction signal “s” by using the estimated frequency error Δωₙ. The multiplier 220 in the cancellation device 20 corrects the frequency of each of, for example, the transmission signals Tx11 and Tx12 by using the correction signal “s.”

In addition, the multiplier 220 may correct the frequency of each of the transmission signals Tx21 and Tx22 or the frequency of each of the transmission signals Tx11 and Tx22, by using the correction signal “s.”

In the present Third Embodiment, the frequency error Δωₙ is estimated by using the compensation coefficient A as in First Embodiment. However, the frequency error Δωₙ may be estimated based on the correlation value Cor(n) between the reception signal Rx′ and the component Z of the high-order term as in Second Embodiment. For example, in this case, the frequency error estimation unit 21 calculates the correlation values Cor(n) for the six respective terms included in the equation (11) above, and calculates the frequency errors Δωₙ based on the calculated correlation values Cor(n). Then, the frequency error estimation unit 21 calculates an average value of the plurality of calculated frequency errors Δωₙ as an estimated value of the frequency error Δωₙ. The frequency error estimation unit 21 may calculate the correlation value Cor(n) by using one of the six terms included in the equation (11) above. For example, the frequency error estimation unit 21 may compare the powers of the six terms included in the equation (11) above, and calculate the correlation value Cor(n) by using the term having the largest power. As a result, the correlation value Cor(n) may be accurately calculated, and the frequency error Δωₙ may be accurately estimated.

In addition, as in First Embodiment, the multiplier 220 may correct the frequency of the component Z of the high-order term, the compensation coefficient A, or the cancellation signal Y by using the correction signal “s.” When the frequency of the component Z of the high-order term, the compensation coefficient A, or the cancellation signal Y is corrected by using the correction signal “s,” the frequency error estimation unit 21 estimates the frequency error Δωₙ for each of the six terms included in the equation (11) above. Then, the frequency error estimation unit 21 generates the correction signal “s” for each of the six terms by using the frequency error Δωₙ estimated for each of the six terms. Then, the multiplier 220 corrects the frequency for each of the six terms by using the correction signal “s.” Specifically, when the frequency of the component Z of the high-order term is corrected, the multiplier 220 corrects the frequency of each term included in the component Z of the high-order term by using the correction signal “s.” In addition, when the frequency of the compensation coefficient A is corrected, the multiplier 220 corrects the frequency of the compensation coefficient A applied to each term included in the component Z of the high-order term by using the correction signal “s.” In addition, when the frequency of the cancellation signal Y is corrected, the multiplier 220 corrects the frequency of each term included in the cancellation signal Y by using the correction signal “s.”

In addition, when the frequency of the component Z of the high-order term, the compensation coefficient A, or the cancellation signal Y is corrected by using the correction signal “s,” the frequency error estimation unit 21 may calculate the frequency errors Δωₙ based on the compensation coefficients of the six respective terms included in the equation (11) above, and generate the correction signal “s” for each of the six terms by commonly using an average value of the plurality of calculated frequency errors Δωₙ. In addition, when the frequency of the component Z of the high-order term, the compensation coefficient A, or the cancellation signal Y is corrected by using the correction signal “s,” the frequency error estimation unit 21 may calculate correlation values Cor(n) for the six respective terms included in, for example, the equation (11) above, and generate the correction signal “s” for each of the six terms by commonly using an average value of the frequency errors Δωₙ calculated based on the correlation values Cor(n) calculated for the respective terms.

In addition, in the present Third Embodiment, the frequency error estimation unit 21 may calculate a frequency deviation of the local oscillation signal generated by each local oscillation signal generation unit, by solving simultaneous equations.

In Third Embodiment described above, the local oscillation signal generation units 32 and 37 in each of the RRHs 30 generate the local oscillation signals by commonly using the reference signal from the BBU 11. However, the present disclosure is not limited thereto. The local oscillation signal generation units 32 and 37 in each of the RRHs 30 may generate the local oscillation signals by using reference signals from reference oscillators mounted on the respective RRHs 30. In this case as well, a frequency deviation of the local oscillation signal generated by each local oscillation signal generation unit may be calculated by simultaneous equations, or an amount of a frequency deviation may be calculated for each replica term of the PIM signal, so that an individual compensation for each term may be performed.

<Effects of Third Embodiment>

Third Embodiment has been described. In this embodiment, the RRH 30-1 up-converts the transmission signals Tx11 and Tx12 to the frequency of f_{D1}+Δf_{D1} and transmits the transmission signals Tx11 and Tx12 from separate antennas, respectively. In addition, the RRH 30-2 up-converts the transmission signals Tx21 and Tx22 to the frequency of f_{D2}+Δf_{D2}, and transmits the transmission signals Tx21 and Tx22 from separate antennas, respectively. In addition, the compensation coefficient updating unit 223 sequentially updates the compensation coefficient for each term included in the component Z of the higher order term generated by the higher-order term generation unit 221. The frequency error estimation unit 21 may estimate the frequency error Δωₙ by using the compensation coefficient sequentially updated by the compensation coefficient updating unit 223 for each term included in the component Z of the high-order term. In addition, the frequency error estimation unit 21 may estimate the frequency error Δωₙ by using one compensation coefficient in the component Z of the high-order term. In this case, the frequency error estimation unit 21 may reduce the process load when estimating the frequency error Δωₙ.

In Third Embodiment described above, the frequency error estimation unit 21 may estimate the frequency error Δωₙ by using the compensation coefficient having the largest value among the plurality of compensation coefficients sequentially updated by the compensation coefficient updating unit 223 for the respective terms included in the generated component of the high-order term. As a result, the frequency error estimation unit 21 may accurately estimate the frequency error Δωₙ.

In Third Embodiment described above, the frequency error estimation unit 21 may estimate the frequency error based on a phase change of the correlation value between the reception signal Rx′ down-converted by the RRH 30 and the component Z of the high-order term generated by the high-order term generation unit 221. In this case, the frequency error estimation unit 21 may calculate the correlation value for each term included in the component Z of the high-order term generated by the high-order term generation unit 221. In addition, the frequency error estimation unit 21 may calculate the correlation value by using one of the terms included in the component Z of the high-order term. In this case, the frequency error estimation unit 21 may reduce the process load when calculating the correlation value.

In Third Embodiment described above, the frequency error estimation unit 21 may calculate the correlation value by using the term having the largest power among the terms included in the component Z of the high-order term generated by the high-order term generation unit 221. As a result, the frequency error estimation unit 21 may accurately calculate the correlation value, and accurately estimate the frequency error Δωₙ by the calculated correlation value.

### Fourth Embodiment

In each of the embodiments described above, the frequency shift amount calculation unit 210 generates the correction signal “s” according to the calculation equation (6) described above based on the estimated frequency shift amount ωₙ, and outputs the generated correction signal “s” to the multiplier 220. The multiplier 220 multiplies a signal input to the position where the multiplier 220 is provided, by the value of the correction signal “s” output from the frequency shift amount calculation unit 210, so as to correct the frequency of the corresponding signal. In this case, the frequency shift amount calculation unit 210 calculates the values of a real part and an imaginary part which correspond to instantaneous values of the correction signal “s,” for example, at each sampling timing, and outputs the calculated values to the multiplier 220. At each sampling timing, the multiplier 220 multiplies the signal input to the position where the multiplier 220 is provided, by the values of the real part and the imaginary part of the correction signal “s” output from the frequency shift amount calculation part 210, so as to correct the frequency of the corresponding signal.

The instantaneous values of the correction signal “s” are sequentially calculated at each sampling timing, in order to accurately perform the frequency correction based on the estimated frequency shift amount ωₙ. However, when a sampling frequency becomes equal to or more than several GHz, it is difficult to sequentially calculate the instantaneous values of the correction signal “s” by software or hardware calculation. Further, when the frequency of the estimated frequency shift amount ωₙ is very small with respect to the sampling frequency, the change of the instantaneous values of the correction signal “s” becomes very small between adjacent sampling timings. Thus, even when the instantaneous values of the correction signal “s” are stored in advance as a look up table (LUT) in a memory, an amount of data which is stored in the LUT becomes large.

Accordingly, in the present Fourth Embodiment, a representative value among values that may be taken as the instantaneous values of the correction signal “s” is stored as an LUT in a memory, and the value stored in the LUT is interpolated, so as to calculate the instantaneous values of the correction signal “s” corresponding to the estimated frequency shift amount ωₙ. Thus, the amount of data which is stored in the memory may be reduced, and the amount of calculation for calculating the instantaneous values of the correction signal “s” may be reduced.

<Cancellation Device 20>

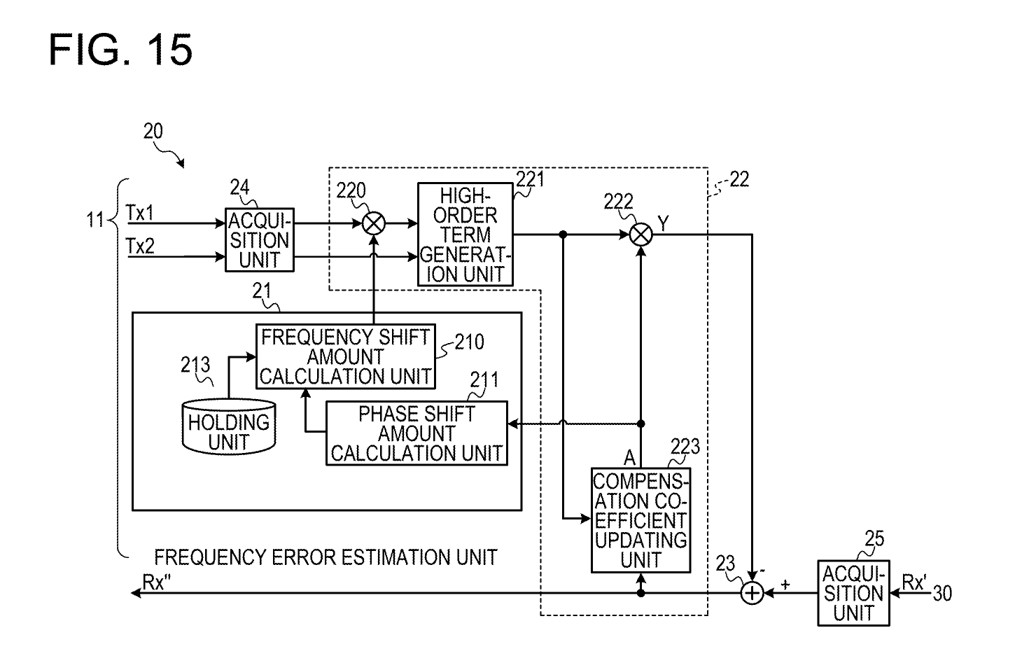

FIG. 15 is a block diagram illustrating an example of a cancellation device 20 according to Fourth Embodiment. In this embodiment, for example, as illustrated in FIG. 15, the cancellation device 20 includes the frequency error estimation unit 21, the generation unit 22, and the combination unit 23. The frequency error estimation unit 21 includes the frequency shift amount calculation unit 210, the phase shift amount calculation unit 211, and the holding unit 213. In FIG. 15, the blocks denoted by the same reference numerals as used in FIG. 3 have the same or similar functions to those of the blocks in FIG. 3, except for the points to be described hereinbelow, and thus, detailed descriptions thereof will be omitted.

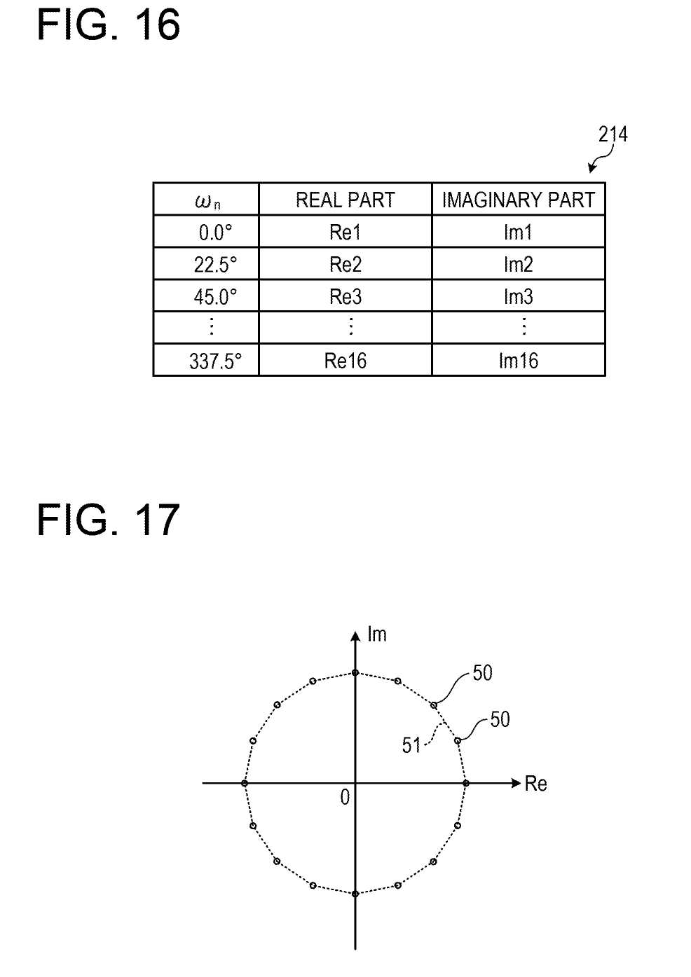

The holding unit 213 holds an instantaneous value table 214 as illustrated in, for example, FIG. 16. FIG. 16 is a view illustrating an example of the instantaneous value table 214. In the instantaneous value table 214, instantaneous values of the real part and the imaginary part of the correction signal “s” at the frequency shift amount ωₙ are registered in advance in association with the frequency shift amount ωₙ. In this embodiment, in the instantaneous value table 214, the instantaneous values of the real part and the imaginary part of the correction signal “s” are registered in advance at, for example, each angle obtained by dividing 360° with 16. In addition, in the instantaneous value table 214, the instantaneous values of the real part and the imaginary part of the correction signal “s” may be registered in advance at, for example, each angle obtained by dividing 360° with a number equal to or more than 16.

The frequency shift amount calculation unit 210 calculates the frequency error Δωₙ according to, for example, the calculation equation (4) described above based on the phase shift amount calculated by the phase shift amount calculation unit 211, and calculates the frequency shift amount ωₙ of the correction signal “s” based on, for example, the calculation equation (5) described above. Then, the frequency shift amount calculation unit 210 specifies a frequency shift amount ωₙ closest to the calculated frequency shift amount ωₙ and a frequency shift amount ωₙ second closest to the calculated frequency shift amount ωₙ, within the instantaneous value table 214 of the holding unit 213.

Then, the frequency shift amount calculation unit 210 specifies the values of the real part and the imaginary part which correspond to each of the two specified frequency shift amounts ωₙ, within the instantaneous value table 214. Then, for example, as illustrated in FIG. 17, the frequency shift amount calculation unit 210 interpolates two points 50 having the specified values of the real part and the imaginary part with a line 51 on a complex plane. FIG. 17 is a view illustrating an example of an interpolating method. In FIG. 17, each point 50 indicates a point represented by the real part and the imaginary part of the correction signal “s” registered in advance in the instantaneous value table 214. The line 51 interpolating the adjacent points 50 may be a straight line or a curved line.

The frequency shift amount calculation unit 210 specifies the values of the real part and the imaginary part of the point which is a point on the interpolating line 51 and corresponds to the calculated frequency shift amount ωₙ, as the values of the real part and the imaginary part of the instantaneous values of the correction signal “s” which correspond to the calculated frequency shift amount ωₙ. Then, the frequency shift amount calculation unit 210 outputs the specified values of the real part and the imaginary part of the correction signal “s” to the multiplier 220. The frequency shift amount calculation unit 210 is an example of a calculation unit. The multiplier 220 multiplies the signal input to the position where the multiplier 220 is provided, by the values of the real part and the imaginary part of the correction signal “s” that have been output from the frequency shift amount calculation unit 210, so as to correct the frequency of the corresponding signal.

<Effects of Fourth Embodiment>

Fourth Embodiment has been described. In this embodiment, the frequency error estimation unit 21 includes the frequency shift amount calculation unit 210 and the holding unit 213. The holding unit 213 holds a predetermined number of instantaneous values among the instantaneous values of the signal corresponding to the frequency error estimated by the frequency shift amount calculation unit 210. The frequency shift amount calculation unit 210 calculates the instantaneous values of the signal corresponding to the estimated frequency error by interpolating the instantaneous values held in the holding unit 213 based on the estimated frequency error. The multiplier 220 multiplies the cancellation signal Y or the signal used for generating the cancellation signal Y by the instantaneous values calculated by the frequency shift amount calculation unit 210, so as to correct the frequency of the cancellation signal Y or the signal used for generating the cancellation signal Y. As a result, the cancellation device 20 may reduce the amount of data which is stored in the memory within the canceling device 20, and reduce the amount of calculation when calculating the instantaneous values of the correction signal “s.”

<Hardware>

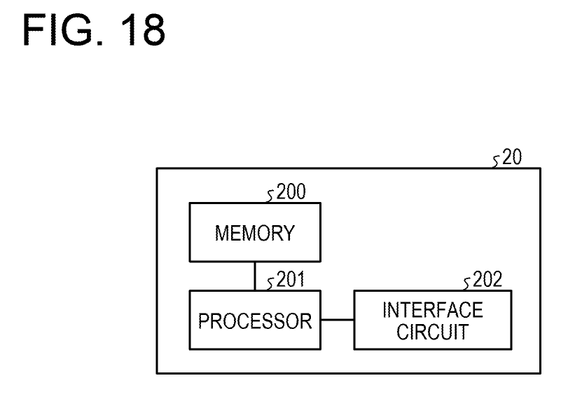

FIG. 18 is a view illustrating an example of hardware of the cancellation device 20. For example, as illustrated in FIG. 18, the cancellation device 20 includes a memory 200, a processor 201, and an interface circuit 202.

The interface circuit 202 performs a transmission and reception of a signal with the BBU 11 and the RRHs 30 according to a communication standard such as the common public radio interface (CPRI). The memory 200 stores programs, data, and others for implementing the functions of the cancellation device 20. The processor 201 executes the program read out from the memory 200 and cooperates with the interface circuit 202 and others so as to implement the respective functions of the cancellation device 20 such as the frequency error estimation unit 21, the generation unit 22, and the combination unit 23.

<Miscellaneous>

The present disclosure is not limited to the embodiments described above and may be modified in various ways within the scope of the technical gist thereof.

For example, in each of Firth to Fourth Embodiments described above, the cancellation device 20 is provided as a separate device from the BBU 11 and the RRHs 30 in the communication device 10. However, the present disclosure is not limited thereto. For example, the cancellation device 20 may be provided in the BBU 11 or in each RRH 30. In addition, the cancellation device 20 may be implemented as a separate device from the communication device 10.

In each of First to Fourth Embodiments described above, the cancellation device 20 is provided in the communication device 10 operating as, for example, a radio base station. However, the present disclosure is not limited thereto. The cancellation device 20 may be provided in the communication device 10 operating as a radio terminal.

All examples and conditional language recited herein are intended for pedagogical purposes to aid the reader in understanding the disclosure and the concepts contributed by the inventor to furthering the art, and are to be construed as being without limitation to such specifically recited examples and conditions, nor does the organization of such examples in the specification relate to a showing of the superiority and inferiority of the disclosure. Although the embodiments of the present disclosure have been described in detail, it should be understood that the various changes, substitutions, and alterations could be made hereto without departing from the spirit and scope of the disclosure.

What is claimed is:

1. A communication device comprising:
a first transmitter configured to up-convert a frequency of a first transmission signal to a first frequency so as to be wirelessly transmitted;
a second transmitter configured to up-convert a frequency of a second transmission signal to a second frequency different from the first frequency so as to be wirelessly transmitted;
a receiver configured to receive a reception signal including a passive intermodulation signal generated due to the first transmission signal wirelessly transmitted and the second transmission signal wirelessly transmitted, and down-convert the reception signal to a baseband signal;
a memory; and
a processor coupled to the memory and the processor configured to:
estimate frequency errors of the up-converted first transmission signal and the up-converted second transmission signal;
generate a cancellation signal into which any frequency of the first transmission signal and the second transmission signal has been corrected, based on the estimated frequency errors, wherein the cancellation signal is a replica signal for the passive intermodulation signal; and
combine the cancellation signal with the down-converted reception signal.

2. The communication device according to claim 1,
wherein the processor is further configured to:
generate a component of a high-order term to be included in the cancellation signal, based on the first transmission signal and the second transmission signal;
sequentially update coefficients applied to the component of the high-order term, based on the component of the high-order term, the down-converted reception signal by the receiver, and the down-converted reception signal with which the cancellation signal is combined;
generate the cancellation signal by applying the updated coefficients to the component of the high-order term;
correct a frequency of the cancellation signal or any frequency of the first transmission signal and the second transmission signal used for generating the cancellation signal, based on the estimated frequency errors; and
estimate the frequency errors, based on a phase change of the sequentially updated coefficients.

3. The communication device according to claim 2,
wherein the processor is further configured to estimate the frequency errors, based on a coefficient corresponding to a third-order component among the sequentially updated coefficients.

4. The communication device according to claim 3,
wherein the first transmitter up-converts a frequency of a third transmission signal to the first frequency so as to be wirelessly transmitted through an antenna different from an antenna through which the first transmission signal is wirelessly transmitted,
wherein the second transmitter up-converts a frequency of a fourth transmission signal to the second frequency so as to be wirelessly transmitted through an antenna different from an antenna through which the second transmission signal is wirelessly transmitted,
wherein the processor is configured to:
sequentially update the coefficients for each term included in the generated component of the high-order term, and
estimate the frequency errors, based on the sequentially updated coefficients for each term included in the component of the high-order term.

5. The communication device according to claim 4,
wherein the processor is configured to estimate the frequency errors by using one of the sequentially updated coefficients for each term included in the component of the high-order term.

6. The communication device according to claim 5,
wherein the processor is configured to estimate the frequency errors, based on a coefficient having a largest value among a plurality of sequentially updated coefficients.

7. The communication device according to claim 1,
wherein the processor is further configured to:
generate a component of a high-order term to be included in the cancellation signal, based on the first transmission signal and the second transmission signal;
sequentially update coefficients applied to the component of the high-order term, based on the component of the high-order term, the down-converted reception signal by the receiver, and the down-converted reception signal with which the cancellation signal is combined;
generate the cancellation signal by applying the updated coefficients to the component of the high-order term; and
correct a frequency of the cancellation signal or any frequency of the first transmission signal and the second transmission signal used for generating the cancellation signal, based on the estimated frequency errors; and
estimate the frequency errors, based on a phase change of a correlation value between the down-converted reception signal by the receiver and the generated component of the high-order term.

8. The communication device according to claim 7,
wherein the processor is further configured to calculate the correlation value, based on a third-order component in the generated component of the high-order term.

9. The communication device according to claim 8,
wherein the first transmitter up-converts a frequency of a third transmission signal to the first frequency so as to be wirelessly transmitted through an antenna different from an antenna through which the first transmission signal is wirelessly transmitted,
wherein the second transmitter up-converts a frequency of a fourth transmission signal to the second frequency so as to be wirelessly transmitted through an antenna different from an antenna through which the second transmission signal is wirelessly transmitted, and
wherein the processor is configured to calculate the correlation value for each term included in the generated component of the high-order term.

10. The communication device according to claim 9,
wherein the processor is configured to calculate the correlation value, based on one of terms included in the generated component of the high-order term.

11. The communication device according to claim 10,
wherein the processor is configured to calculate the correlation value, based on a term having a largest power among the terms included in the generated component of the high-order term.

12. The communication device according to claim 2,
wherein the processor is further configured to:
hold a predetermined instantaneous value among instantaneous values of the first transmission signal or the second transmission signal corresponding to the estimated frequency errors; and
calculate the instantaneous values of the first transmission signal or the second transmission signal corresponding to the estimated frequency errors, by interpolating the instantaneous values held by the processor, based on the estimated frequency errors, and
correct a frequency of the cancellation signal or any frequency of the first transmission signal and the second transmission signal used for generating the cancellation signal, by multiplying the cancellation signal or any signal of the first transmission signal and the second transmission signal used for generating the cancellation signal by the calculated instantaneous values.

13. The communication device according to claim 2,
wherein the processor is configured to correct a frequency of at least one of the first transmission signal and the second transmission signal, based on the frequency errors.

14. The communication device according to claim 2,
wherein the processor is configured to correct a frequency of any one of the generated component of the high-order term, the sequentially updated coefficients, and the generated cancellation signal.

15. A communication method comprising:
up-converting a frequency of a first transmission signal to a first frequency so as to be wirelessly transmitted, by a first transmitter;
up-converting a frequency of a second transmission signal to a second frequency different from the first frequency so as to be wirelessly transmitted, by a second transmitter;
receiving a reception signal including a passive intermodulation signal generated due to the first transmission signal wirelessly transmitted and the second transmission signal wirelessly transmitted and down-converting the reception signal to a baseband signal, by a receiver;
estimating frequency errors of the up-converted first transmission signal and the up-converted second transmission signal, by a processor;
generating a cancellation signal into which any frequency of the first transmission signal and the second transmission signal has been corrected, based on the estimated frequency errors, wherein the cancellation signal is a replica signal for the passive intermodulation signal, by the processor; and
combing the cancellation signal with the down-converted reception signal, by the processor.

16. A cancellation device comprising:
a memory; and
a processor coupled to the memory and the processor configured to:
acquire a first transmission signal having an up-converted first frequency and a second transmission signal having an up-converted second frequency different from the first frequency, the up-converted first and second transmission signals to be wirelessly transmitted;
acquire a reception signal including a passive intermodulation signal generated due to the up-converted first and second transmission signals wirelessly transmitted, and down-convert the reception signal to a baseband signal;
estimate frequency errors of the up-converted first and second transmission signals;
generate a cancellation signal into which any frequency of the first and second transmission signals has been corrected, based on the estimated frequency errors, wherein the cancellation signal is a replica signal for the passive intermodulation signal; and
combine the cancellation signal with the down-converted reception signal.
